(19) United States
(12) Patent Application Publication
(10) Pub. No.: US 2023/0180492 A1
(43) Pub. Date: Jun. 8, 2023

(54) ORGANIC ELECTROLUMINESCENT DEVICE

(71) Applicant: BEIJING SUMMER SPROUT TECHNOLOGY CO., LTD., Beijing (CN)

(72) Inventors: Menglan Xie, Beijing (CN); Huiqing Pang, Beijing (CN)

(73) Assignee: BEIJING SUMMER SPROUT TECHNOLOGY CO., LTD., Beijing (CN)

(21) Appl. No.: 18/074,727

(22) Filed: Dec. 5, 2022

(30) Foreign Application Priority Data
Dec. 6, 2021 (CN) 202111471907.2

(51) Int. Cl. H10K 50/11; H10K 85/60

(52) U.S. Cl. CPC H01L 51/5004; H01L 51/0069; H01L 51/0073; H01L 51/504

(57) ABSTRACT

Provided is a new organic electroluminescent device. This new organic electroluminescent device comprises multiple light-emitting units, a second organic layer and a specific connection layer. This new organic electroluminescent device controls LUMO_{first organic material} - work functionₘₑₜₐₗ to be ≤ 2.1 eV, which can promote a separation of electrons at metal and organic interfaces, suppressing a recombination of carriers at the interfaces. HOMO_{second organic material} -LUMO_{first organic material} is controlled to be ≥ 0.3 V, and a hole injection is controlled through an adjustment of a doping concentration of a first organic material, which can balance a recombination of the carriers on a light-emitting layer, significantly improving efficiency and a lifetime of the device and reducing power consumption of the device. This new tandem organic electroluminescent device has more excellent device performance and broader application prospects.

### CROSS-REFERENCE TO RELATED APPLICATION(S)

This application claims priority to Chinese Patent Application No. 202111471907.2 filed on Dec. 6, 2021, the disclosure of which is incorporated herein by reference in its entirety.

### TECHNICAL FIELD

The present disclosure relates to an organic electroluminescent device. More particularly, the present disclosure relates to an organic electroluminescent device comprising multiple light-emitting units and a specific connection layer.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

An organic electroluminescent device (such as an OLED) is composed of a cathode, an anode and organic light-emitting materials stacked between the cathode and the anode, converts electrical energy into light through a voltage applied at both the cathode and the anode of the device, and has the advantages of a wide angle, a high contrast and a faster response time. In 1987, Tang and Van Slyke of Eastman Kodak reported an organic light-emitting device, which includes an arylamine hole transporting layer and a tris-8-hydroxyquinolato-aluminum layer as an electron transporting layer and a light-emitting layer (Applied Physics Letters, 1987, 51 (12): 913-915). Once the voltage is applied to both ends of the device, green light is emitted from the device. This device laid the foundation for the development of modern organic light-emitting diodes (OLEDs). Since the OLED is a self-luminescent solid-state thin film device, it provides great potential for display and lighting applications.

In terms of device structure, the OLED can be classified into a conventional OLED of a monolayer structure and an OLED of a tandem structure (also called a stacked structure). The conventional OLED of a monolayer structure comprises only one light-emitting unit between the cathode and the anode, while the OLED of a tandem structure has multiple light-emitting units stacked. Adjacent light-emitting units of the tandem OLED are connected by a charge generation layer, and performance of the charge generation layer directly affects parameters of the tandem OLED such as voltage, lifetime and efficiency. Typically, the charge generation layer comprises an n-type material and a p-type material to generate electrons and holes. U.S. Pat. Publication No. 2010/0288362 A1 has disclosed an internal connection structure of a stacked OLED device. The internal connection structure comprises a p-type layer, an intermediate layer (IL) (preferably such as CuPc) and an n-type layer. The IL, the p-type layer and the n-type layer are in close contact with each other. The IL comprises a p-type compound having a LUMO energy level greater than 3.0 eV, and the p-type layer comprises a hole transporting material having an arylamine structure and a p-type doped material (PD), where the PD has a LUMO energy level greater than 4.5 eV. The application specifically indicates that the p-type compound of the IL is different from the p-type doped material of the p-type layer. Although the patent application indicates that the addition of the IL can improve stability of the device, the disclosed internal connection structure comprises no metal layer, the disclosed technical solution differs in the materials of the IL and the p-type layer, and the patent application does not focus on balancing an energy level relationship between the IL and the p-type layer. However, the energy level relationship between the two has an important effect on device performance. A large energy level difference easily causes an interface problem, which affects a carrier transport, and too many types of materials may increase a device preparation cost.

CN Patent Publication No. 112687811A has disclosed an organic electroluminescent device where a specific connection layer is used for connecting two light-emitting units and comprises a specific organic buffer layer and a metal layer. However, it is considered that the buffer layer has a shallow LUMO energy level and a weak hole injection ability, which is prone to causing a voltage and lifetime of the device not to meet a requirement. Therefore, an organic material having a deeper energy level requires to be used as the buffer layer, and the LUMO energy level of the organic material is limited to be greater than 4.9 eV. In addition, the patent application pays no attention to an effect of an energy level relationship between the buffer layer and the metal layer on device performance. Therefore, compared with a device comprising no organic buffer layer, although the disclosed tandem organic electroluminescent device comprising the specific connection layer and the two light-emitting units has a significant improvement in the lifetime and voltage of the device, external quantum efficiency is not significantly improved so that overall performance of the device requires to be further improved.

Since the tandem organic electroluminescent device has a relatively thick device structure, a yield rate of a production line can be improved, and a current density required by the tandem organic electroluminescent device is less than that required by the conventional monolayer OLED, achieving an effect of prolonging the lifetime. In addition, the efficiency of the device can be multiplied. Therefore, the field of tandem OLED devices has also received more and more attention from relevant practitioners. Performance of a connection layer (a charge generation layer) has a crucial effect on performance of the entire tandem OLED device. Therefore, it is an important problem to be solved urgently to develop more new connection layer structures and further improve the performance of the stacked OLED device to obtain a lower voltage, a longer lifetime and a more simplified production process.

### SUMMARY

The present disclosure aims to provide a new tandem organic electroluminescent device to solve at least part of the above problems. The tandem organic electroluminescent device comprises multiple light-emitting units, a second organic layer and a specific connection layer, where the connection layer comprises a metal layer and a first organic layer. The electroluminescent device improves an electron injection ability through adjusting a difference between a LUMO energy level of a first organic material of the first organic layer and a work function of a metal material of the metal layer; and controls a hole injection through adjusting a difference between a HOMO energy level of a second organic material of the second organic layer connected to the first organic layer and the LUMO energy level of the first organic material. The tandem electroluminescent device using the connection layer and the second organic layer can effectively separate and inject electrons and holes, significantly improving efficiency of the device and achieving a low voltage and a long lifetime of the device.

According to an embodiment of the present disclosure, an organic electroluminescent device is disclosed. The organic electroluminescent device includes:
a first electrode,
a second electrode, and
at least two light-emitting units disposed between the first electrode and the second electrode,
wherein each of the light-emitting units comprises at least one light-emitting layer;
a connection layer is further disposed between the at least two light-emitting units, and the connection layer comprises a metal layer and a first organic layer, wherein the first organic layer comprises a first organic material whose LUMO energy level is LUMO_{first organic material}, and the metal layer comprises at least one metal material whose work function is work functionₘₑₜₐₗ, wherein LUMO_{first organic material} - work functionₘₑₜₐₗ ≤ 2.1 eV; and
the light-emitting unit in contact with the first organic layer further comprises a second organic layer, wherein the second organic layer comprises a second organic material and the first organic material, wherein a HOMO energy level of the second organic material is HOMO_{second organic material}, and HOMO_{second organic material} — LUMO_{first organic material} ≥ 0.3 eV.

According to another embodiment of the present disclosure, an electronic assembly is further disclosed. The electronic assembly comprises the organic electroluminescent device in the preceding embodiment.

The tandem organic electroluminescent device disclosed in the present disclosure comprises the multiple light-emitting units, the second organic layer and the specific connection layer, where the connection layer comprises the metal layer and the first organic layer. The electroluminescent device improves the electron injection ability through adjusting the difference between the LUMO energy level of the first organic material of the first organic layer and the work function of the metal of the metal layer and controls the hole injection through adjusting the difference between the HOMO energy level of the second organic material of the second organic layer in the light-emitting unit in contact with the first organic layer and the LUMO energy level of the first organic material. The tandem electroluminescent device using the connection layer and the second organic layer can effectively separate and inject the electrons and the holes, significantly improving the efficiency of the device and achieving a low voltage and a long lifetime of the device.

### BRIEF DESCRIPTION OF DRAWINGS

FIG. 1 is a sectional view of a tandem organic electroluminescent device 100 of the present disclosure.

FIG. 2 is a sectional view of a monolayer organic electroluminescent device 200.

### DETAILED DESCRIPTION

In terms of device structure, an OLED can be classified into a conventional OLED of a monolayer structure and an OLED of a tandem structure (also called a stacked structure). The conventional OLED comprises only one light-emitting unit between a cathode and an anode while the tandem OLED has multiple light-emitting units stacked. One light-emitting unit generally comprises at least one light-emitting layer, one hole transporting layer and one electron transporting layer. Besides the above-mentioned layers, the light-emitting unit may further comprise a hole injection layer, an electron injection layer, a hole blocking layer and an electron blocking layer. Note that although the conventional monolayer OLED has only one light-emitting unit, the light-emitting unit may comprise multiple light-emitting layers, for example, the light-emitting unit may comprise a yellow light-emitting layer and a blue light-emitting layer. However, each light-emitting unit generally comprises one hole transporting layer and one electron transporting layer. The tandem OLED comprises at least two light-emitting units, that is, the tandem OLED generally comprises at least two pairs of hole transporting layers and electron transporting layers. When multiple light-emitting units are arranged in a vertically-stacked physical form, which achieves a tandem characteristic on a circuit, this kind of OLED is referred to as the tandem OLED (in terms of the circuit connection) or the stacked OLED (in terms of the physical form). That is, under the same brightness, the current density required by the tandem OLED is less than that required by the conventional monolayer OLED, achieving an effect of prolonging a lifetime. On the contrary, at the same current density, brightness of the tandem OLED is higher than that of the conventional monolayer OLED, but a voltage of the tandem OLED tends to increase accordingly. Adjacent light-emitting units of the tandem OLED are connected by a connection layer (also referred to as a charge generation layer), and performance of the connection layer directly affects parameters of the tandem OLED such as voltage, lifetime and efficiency. Therefore, a region of the connection layer is required to be able to effectively generate holes and electrons and smoothly inject the holes and the electrons to corresponding light-emitting units, and greater light transmittance in a visible range is better. Moreover, the region of the connection layer is required to have stable performance and be easy to prepare.

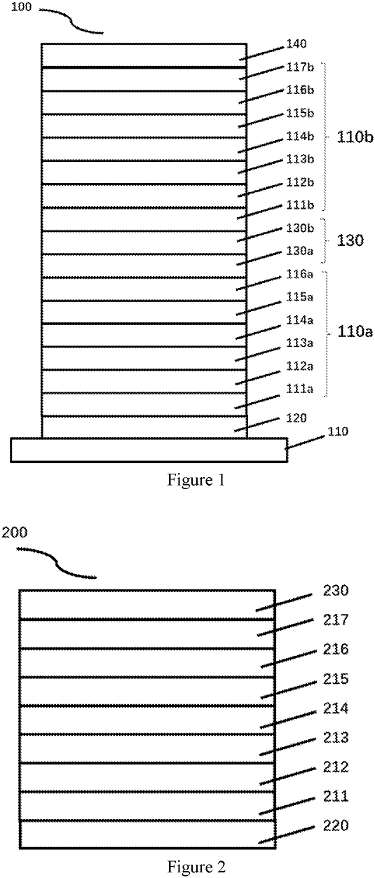

The OLED can be fabricated on various types of substrates such as glass, plastic and metal. FIG. 1 schematically shows a sectional view of a tandem organic electroluminescent device 100 without limitation. The figure is not necessarily drawn to scale. Some of the layer structures in the figure can also be omitted as required. The tandem organic electroluminescent device 100 includes a substrate 110, a first electrode 120, a first light-emitting unit 110a, a second light-emitting unit 110b, a second electrode 140 and a connection layer 130, where the connection layer includes a metal layer 130a and a first organic layer 130b. The substrate 110 may be a substrate having high light transmittance or a bendable substrate, such as glass, plastic or metal. OLED devices may also be classified into bottom-emitting OLED devices and top-emitting OLED devices. The bottom-emitting OLED device refers to an OLED device emitting light from the substrate, and the top-emitting OLED device refers to an OLED device emitting light from the second electrode of the device.

The first electrode 120 is formed on the substrate 110. The first electrode may be a transparent anode of the organic electroluminescent device 100, such as indium tin oxide (ITO), indium zinc oxide (IZO) and indium gallium zinc oxide (IGZO), and such electrode is generally used for preparing a bottom-emitting or transparent device. The first electrode may also be a combined layer that implements a specular reflection, such as a stack of ITO/silver (Ag)/ITO, and such electrode is generally used for preparing a top-emitting device. The second electrode 140 is disposed to face the first electrode 120 and is generally a cathode of the organic electroluminescent device 100. The second electrode 140 may be one of or a combination of two or more of elements of aluminum, magnesium, silver, gold, calcium or ytterbium. Aluminum is generally used as the second electrode of the bottom-emitting device, while magnesium, silver or a magnesium-silver alloy is generally used as the second electrode of the top-emitting device.

Two light-emitting units 110a and 110b are formed between the first electrode 120 and the second electrode 140. The first light-emitting unit 110a and the second light-emitting unit 110b may emit light of the same color, or light of different colors, such as a mixture of orange light and blue light, so that the device emits white light. Each light-emitting unit further includes at least a hole injection layer 111a or 111b, a hole transporting layer 112a or 112b and an electron transporting layer 116a or 116b, and the second light-emitting unit further includes an electron injection layer 117b. Further, the light-emitting unit may further include one or more of electron blocking layers 113a and 113b and hole blocking layers 115a and 115b. The hole injection layer of the second light-emitting unit may be composed of a single hole injection material or hole transporting material, or may be composed of an organic hole transporting material doped with a dopant, and the dopant may be a first organic material of the first organic layer. The thickness of each layer can be adjusted according to optimization results. Each light-emitting unit may further include one or two light-emitting layers that emit different colors.

The connection layer 130 is formed between the light emitting units 110a and 110b. When the tandem organic electroluminescent device 100 operates, the metal layer 130a can provide electrons to the first light-emitting unit 110a close to the anode 120, and these electrons form excitons with holes injected from the anode 120. At the same time, the first organic layer 130b provides or transports holes to the second light-emitting unit 110b close to the cathode 140, and these holes form excitons with electrons injected from the cathode 140. Therefore, in the case where only one electron and only one hole are injected from the cathode 140 and the anode 120, the device can generate two excitons by itself, so that efficiency of the device can theoretically be up to twice as high as that of a conventional monolayer OLED.

The connection layer 130 may be prepared in any suitable manner, such as vacuum vapor deposition, vacuum thermal evaporation, sputtering, solution spin coating, inkjet printing and organic gasification printing. The metal layer 130a may be prepared in a vacuum chamber specific to prepare a metal, and the first organic layer 130b may be prepared in a vacuum chamber specific to prepare an organic material. The advantage is that it avoids cross contamination of the metal and the organic material during the preparation, further improving device performance. Moreover, the dopant in the hole injection layer (i.e., the second organic layer) is used as the first organic material of the first organic layer so that the number of evaporation sources can be further saved. Furthermore, a layer which is generally in contact with the first organic layer is the hole injection layer (i.e., the second organic layer) of the second light-emitting unit, and since these two layers are generally prepared by the same material (the material of the first organic layer is used as the dopant of the hole injection layer), the preparation process (usually an evaporation process) is more continuous, and an interface between the films can be transitioned more smoothly.

The metal layer 130a in the connection layer 130 is used for generating and transporting electrons. Therefore, the metal material has a unique advantage and may be selected from Yb, Li, Rb, Cs, Be, Mg, Ca, Sr, Ba, La, Ce, Pr, Nd, Sm, Eu, Y, Mn and Ag metals or a combination of the above multiple metals; preferably, a work function of the metal layer 130a is less than 4.0 eV, such as Yb, Mg and Ca. The metal layer 130a has a thickness ranging from 0.1 nm to 20 nm, preferably from 0.1 nm to 5 nm. The thinner the metal layer, the higher the transmittance, which is conducive to improving luminescence efficiency. In the present disclosure, the visible light transmittance of the connection layer is greater than 70%, preferably greater than 80%. Since the metal layer 130a is very thin, a discontinuous thin film is formed, which allows the surface to have certain roughness while maintaining excellent electron transporting performance, so that the first organic material of the first organic layer 130b can be better attached to the metal layer 130a. The first organic material is an organic material having a hole generation or transporting ability. The first organic material may be a dopant material used in the hole injection layer, or may be other hole injection or transporting layer materials. A LUMO energy level of the first organic material is ≤ 4.9 eV, more preferably ≤ 4.7 eV. The first organic layer 130b has a thickness ranging from 0.1 nm to 30 nm, preferably from 0.1 nm to 15 nm. Since the first organic layer 130b may be very thin, a discontinuous thin film is also formed so that the surface also has certain roughness, which is complementary to the metal layer 130a.

A process of forming the metal thin film is as follows: on a surface of the substrate, atoms form some uniform, small and moveable groups of atoms which are also called “islands”; these islands continue to accept new deposited atoms and merge with other islands to gradually become bigger; in the process of merging, new islands are gradually formed on the surface of the substrate which is vacated due to the merging, and then the new islands merge again; the process continues until all isolated islands are joined together to form a structurally continuous thin film, and when the isolated islands are not joined together, a formed film is a discontinuous film. In an example embodiment herein, the metal layer of the connection layer is ytterbium, and the ytterbium metal has an atomic radius of 2.4 angstroms (https://www.lookchem.cn/yuansu/101/). When an evaporated thin film has a thickness of 10 angstroms (Å), which is equivalent to a thickness of only two atoms, the two atoms can only form an isolated island, and in this case, a formed film is a discontinuous film.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between. Similarly, the expression that the first layer is “in contact with” the second layer means that there is no other layers between the first and second layers.

The transmittance herein refers to a percentage of a transmitted light flux passed through a measured thin film to an incident light flux, measured in the visible range (380-780 nm). Transmittance of different thin films generally varies with a wavelength of incident light. The transmittance described herein refers to a maximum value of the transmittance in the visible range.

The light-emitting unit herein refers to a unit of an organic material layer that can emit light with a voltage or current applied, and the light-emitting unit may include one or more light-emitting layers. The light-emitting unit generally further includes one or more organic material layers to inject or transport charges. For example, besides the light-emitting layer, the light-emitting unit may further include at least a hole injection layer, a hole transporting layer, an electron blocking layer, a hole blocking layer, an electron transporting layer and an electron injection layer. For example, in an example embodiment of the present disclosure, a light-emitting unit close to the anode is composed of a hole injection layer, a hole transporting layer, an electron blocking layer, a light-emitting layer, a hole blocking layer and an electron transporting layer in sequence, and a light-emitting unit close to the cathode is composed of a hole injection layer, a hole transporting layer, an electron blocking layer, a light-emitting layer, a hole blocking layer, an electron transporting layer and an electron injection layer. In an embodiment, an OLED device may be described as an OLED device having an “organic layer” disposed between the cathode and the anode. The organic layer may include one or more layers.

The work function of the metal material herein refers to a minimum energy required to move one electron from an interior of an object to a surface of the object. All the “work functions of the metal” herein are represented by absolute values (positive values), that is, the higher the value, the more the energy required to pull the electron to a vacuum energy level, and as described herein, a magnitude of the “work function of the metal” means a magnitude of the absolute value. For example, “the work function of the metal is greater than 5.0 eV” means that the energy required to pull the electron to the vacuum energy level is greater than 5.0 eV.

Herein, the highest occupied molecular orbital (HOMO) energy level and the lowest unoccupied molecular orbital (LUMO) energy level of the organic material are measured through an electrochemical cyclic voltammetry method. Herein, all the “HOMO energy levels” and the “LUMO energy levels” are represented by absolute values (positive values), that is, the greater the value, the deeper the energy level. Herein, the expression that the energy level is greater than a certain number means that the energy level is greater than this number in value, that is, the energy level is deeper. For example, “the HOMO energy level of the second organic material is ≥ 5.1 eV” means that an absolute value of the HOMO energy level of the second organic material is greater than or equal to 5.1 eV. Herein, the difference between the LUMO energy level of the first organic material and the HOMO energy level of the second organic material is defined as “HOMO_{second organic material} — LUMO_{first organic material}”, and since the HOMO energy level of the transporting material is generally deeper, this difference is generally a positive value. The difference between the LUMO energy level of the first organic material and the work function of the metal is defined as “LUMO_{first organic material} - work functionₘₑₜₐₗ”.

As used herein, a “connection layer” is a layer disposed between two light-emitting units to provide electrons and holes, also referred to as a charge generation layer. The connection layer is composed of a metal layer and a first organic layer, where the metal layer is in contact with an electron transporting layer or an electron injection layer of one light-emitting unit, and the first organic layer is in contact with a hole injection layer or a hole transporting layer of an adjacent light-emitting unit.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

### Definition of Terms of Substituents

Halogen or halide - as used herein includes fluorine, chlorine, bromine, and iodine.

Alkyl - as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl - as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl - as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl - as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl - as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group - as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle - as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl - as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy - as used herein, is represented by -O-alkyl, -O-cycloalkyl, -O-heteroalkyl, or -O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy - as used herein, is represented by -O-aryl or -O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl - as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl - as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl - as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl - as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl - as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refer to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

In the present disclosure, the number of ring atoms refers to the number of atoms constituting the ring itself in a compound (e.g., a monocyclic compound, a fused ring compound, a cross-linking compound, a carbocyclic compound, a heterocyclic compound) having a structure whose atoms are bonded in a form of ring. When the ring is substituted by a substituent, atoms included in the substituent are not included in the number of ring atoms. The “number of ring atoms” recorded herein has the same meaning unless otherwise specified.

The expression that adjacent substituents can be optionally joined to form a ring is also intended to mean that two substituents bonded to the same carbon atom are joined to each other via a chemical bond to form a ring, which can be exemplified by the following formula:

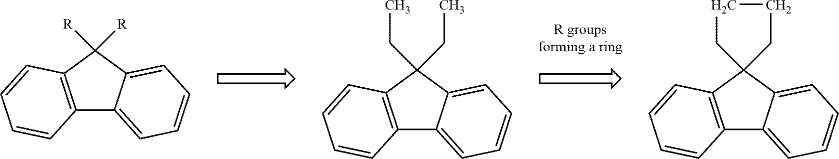

The expression that adjacent substituents can be optionally joined to form a ring is also intended to mean that two substituents bonded to carbon atoms which are directly bonded to each other are joined to each other via a chemical bond to form a ring, which can be exemplified by the following formula:

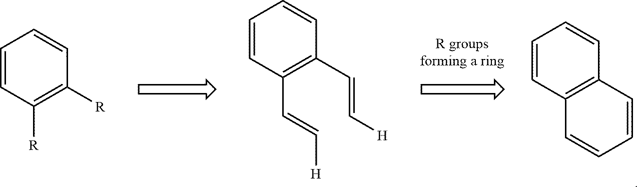

The expression that adjacent substituents can be optionally joined to form a ring is also intended to mean that two substituents bonded to a further distant carbon atom are joined to each other via a chemical bond to form a ring, which can be exemplified by the following formula:

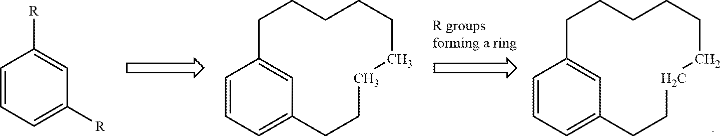

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

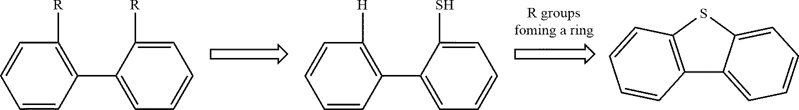

According to an embodiment of the present disclosure, an organic electroluminescent device is disclosed. The organic electroluminescent device includes:
a first electrode,
a second electrode, and
at least two light-emitting units disposed between the first electrode and the second electrode,
wherein each of the light-emitting units comprises at least one light-emitting layer;
a connection layer is further disposed between the at least two light-emitting units, and the connection layer comprises a metal layer and a first organic layer, wherein the first organic layer comprises a first organic material whose LUMO energy level is LUMO_{first organic material}, and the metal layer comprises at least one metal material whose work function is work functionₘₑₜₐₗ, wherein LUMO_{first organic material} - work functionₘₑₜₐₗ ≥ 2.1 eV; and
the light-emitting unit in contact with the first organic layer further comprises a second organic layer, wherein the second organic layer comprises a second organic material and the first organic material, wherein a HOMO energy level of the second organic material is HOMO_{second organic material}, and HOMO_{second organic material} — LUMO_{first organic material} ≥ 0.3 eV.

According to an embodiment of the present disclosure, the LUMO energy level of the first organic material is ≥ 4.7 eV.

According to an embodiment of the present disclosure, the first organic material has a structure represented by one of Formula 1 to Formula 3:

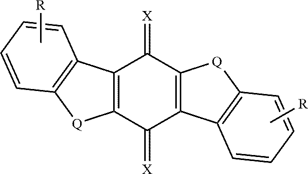

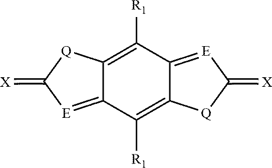

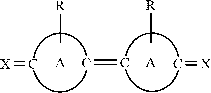

wherein in Formula 1, Formula 2 or Formula 3,
E is, at each occurrence identically or differently, selected from CR₁;
X is, at each occurrence identically or differently, selected from the group consisting of NR′, CR″R‴, O, S and Se;
the ring A is, at each occurrence identically or differently, a five-membered heterocyclic ring containing one intracyclic double bond, at least one N atom and at least one Q;
Q is, at each occurrence identically or differently, selected from the group consisting of O, S, Se and NR_{N};
R represents, at each occurrence identically or differently, mono-substitution, multiple substitutions or non-substitution;
R, R₁, R′, R″, R‴ and R_{N} are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof;
at least one of substituents R, R₁, R′, R″ and R‴ is a group having at least one electron-withdrawing group; and
adjacent substituents R, R′, R″, R‴ can be optionally joined to form a ring.

In this embodiment, the expression that adjacent substituents R, R′, R″, R‴ can be optionally joined to form a ring is intended to mean that any one or more of groups of adjacent substituents, such as adjacent substituents R, adjacent substituents R″ and R‴, adjacent substituents R and R″, adjacent substituents R and R‴, and adjacent substituents R and R′, can be joined to form a ring. Obviously, it is possible that none of these adjacent substituents are joined to form a ring.

According to an embodiment of the present disclosure, the first organic material has a structure represented by Formula 1 or Formula 2.

According to an embodiment of the present disclosure, the first organic material has a structure represented by Formula 3-1:

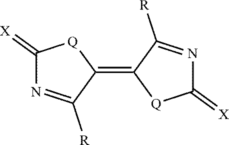

wherein X is, at each occurrence identically or differently, selected from NR′, CR″R‴, O, S or Se;
at least one of R, R′, R″ and R‴ is a group having at least one electron-withdrawing group;
Q is, at each occurrence identically or differently, selected from the group consisting of O, S, Se and NR_{N}; and
R, R′, R″, R‴ and R_{N} are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof.

According to an embodiment of the present disclosure, in Formula 1, Formula 2, Formula 3 or Formula 3-1, X is, at each occurrence identically or differently, selected from CR″R‴ or NR′, and each of R′, R″ and R‴ is a group having at least one electron-withdrawing group.

According to an embodiment of the present disclosure, in Formula 1, Formula 2, Formula 3 or Formula 3-1, X is, at each occurrence identically or differently, selected from CR″R‴ or NR′, and each of R, R′, R″ and R‴ is a group having at least one electron-withdrawing group.

According to an embodiment of the present disclosure, in Formula 1, Formula 2, Formula 3 or Formula 3-1, X is, at each occurrence identically or differently, selected from the group consisting of the following structures:

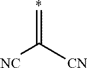

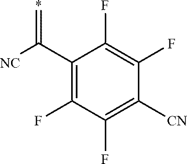

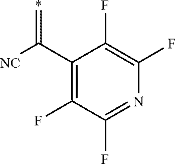

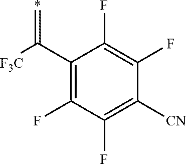 [SMILES: *=C(c1c(F)c(F)c(C#N)c(F)c1F)C(F)(F)F]

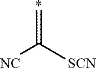

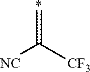

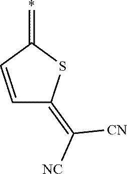

According to an embodiment of the present disclosure, in Formula 1, Formula 2, Formula 3 or Formula 3-1, X is selected from X-1.

According to an embodiment of the present disclosure, in Formula 1, Formula 2, Formula 3 or Formula 3-1, Q is, at each occurrence identically or differently, selected from O or S.

According to an embodiment of the present disclosure, in Formula 1, Formula 2, Formula 3 or Formula 3-1, R and R₁ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, unsubstituted alkyl having 1 to 20 carbon atoms, unsubstituted cycloalkyl having 3 to 20 ring carbon atoms, unsubstituted alkoxy having 1 to 20 carbon atoms, unsubstituted alkenyl having 2 to 20 carbon atoms, unsubstituted aryl having 6 to 30 carbon atoms, unsubstituted heteroaryl having 3 to 30 carbon atoms, any one of the following groups substituted with one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group and a phosphoroso group: alkyl having 1 to 20 carbon atoms, cycloalkyl having 3 to 20 ring carbon atoms, alkoxy having 1 to 20 carbon atoms, alkenyl having 2 to 20 carbon atoms, aryl having 6 to 30 carbon atoms and heteroaryl having 3 to 30 carbon atoms, and combinations thereof.

According to an embodiment of the present disclosure, in Formula 1, Formula 2, Formula 3 or Formula 3-1, R and R₁ are, at each occurrence identically or differently, selected from the group consisting of: hydrogen, deuterium, methyl, isopropyl, NO₂, SO₂CH₃, SCF₃, C₂F₅, OC₂F₅, OCH₃, diphenylmethylsilyl, phenyl, methoxyphenyl, p-methylphenyl, 2,6-diisopropylphenyl, biphenyl, polyfluorophenyl, difluoropyridyl, nitrophenyl, dimethylthiazolyl, vinyl substituted by one or more of CN or CF₃, acetenyl substituted by one of CN or CF₃, dimethylphosphoroso, diphenylphosphoroso, F, CF₃, OCF₃, SF₅, SO₂CF₃, cyano, isocyano, SCN, OCN, trifluoromethylphenyl, trifluoromethoxyphenyl, bis(trifluoromethyl)phenyl, bis(trifluoromethoxy)phenyl, 4-cyanotetrafluorophenyl, phenyl or biphenyl substituted with one or more of F, CN or CF₃, tetrafluoropyridyl, pyrimidinyl, triazinyl, diphenylboryl, oxaboraanthryl and combinations thereof.

According to an embodiment of the present disclosure, the first organic material is selected from the group consisting of the following structures:

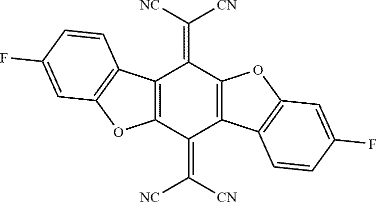

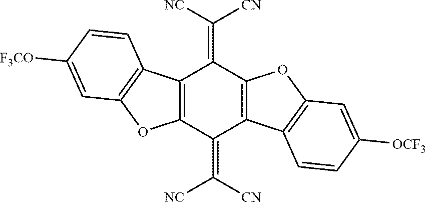

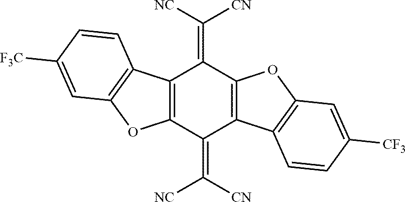

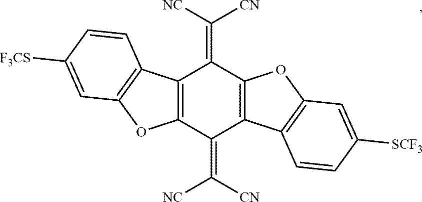

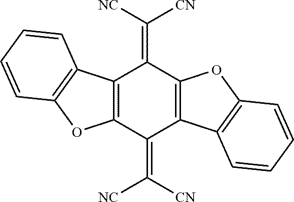

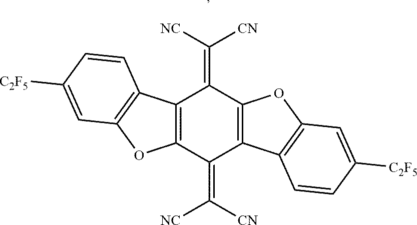

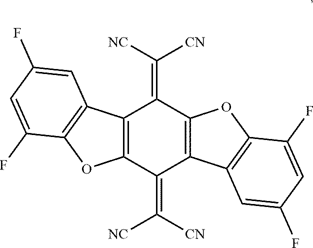

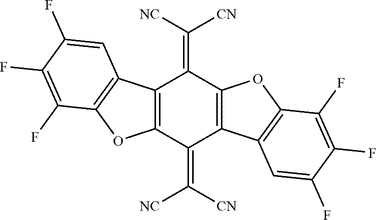

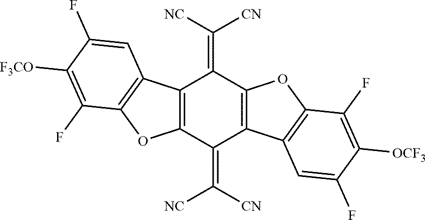

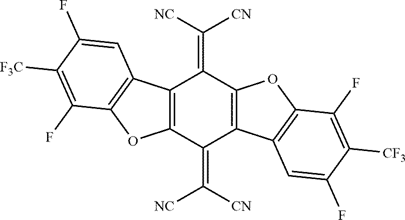

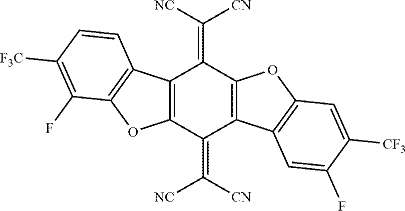

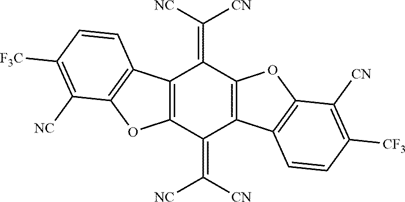

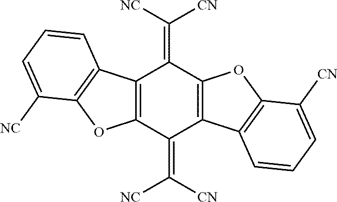

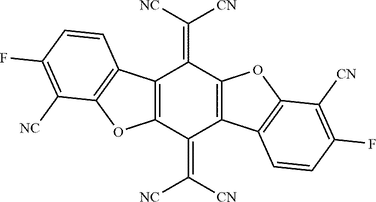

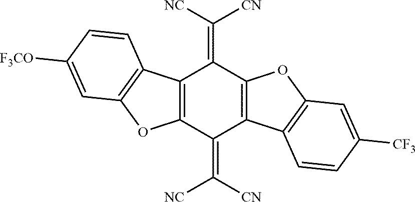

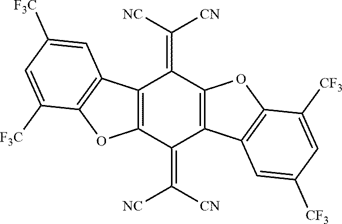

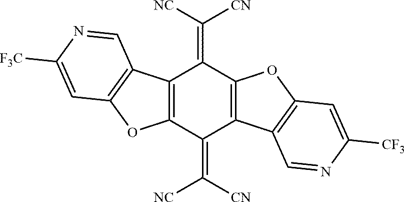

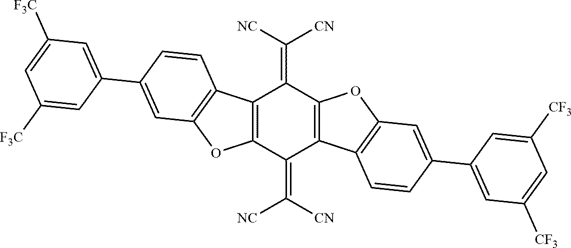

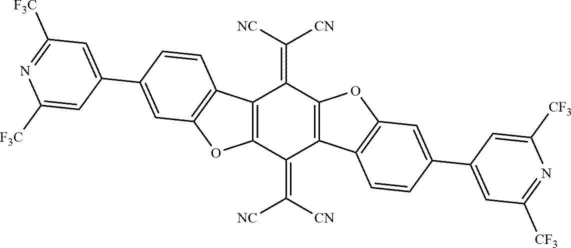

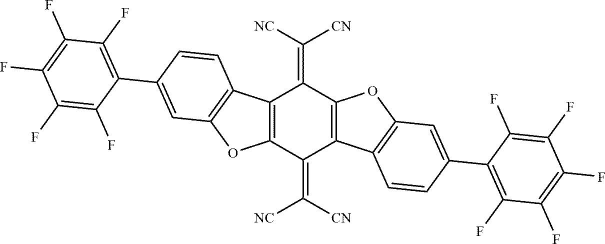

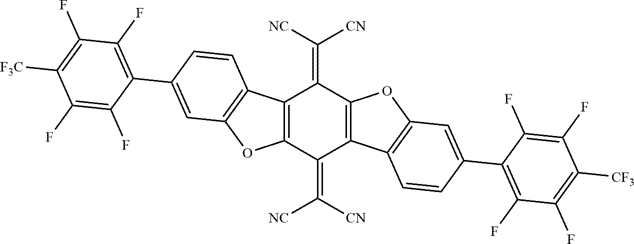

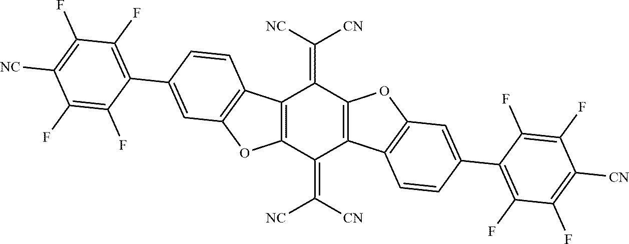

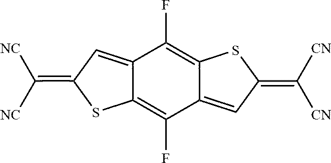

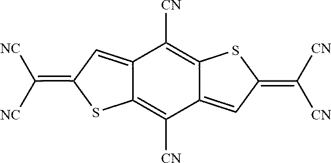

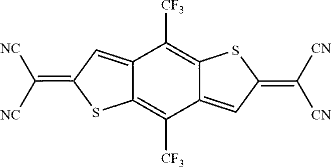

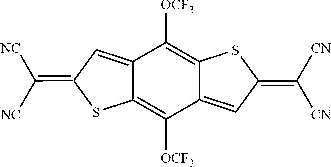

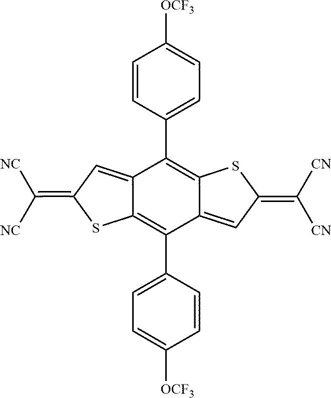

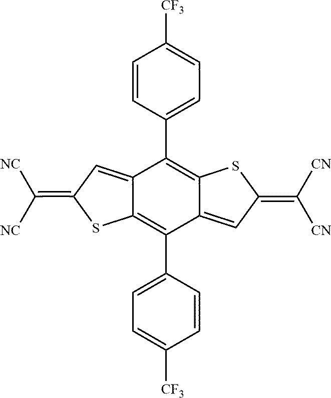

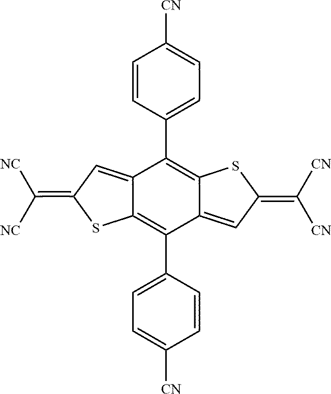

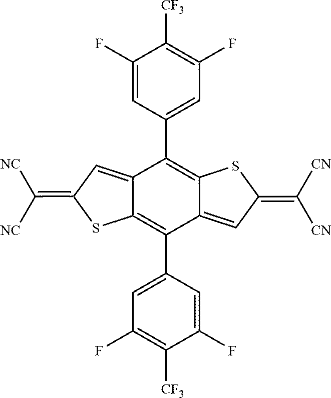

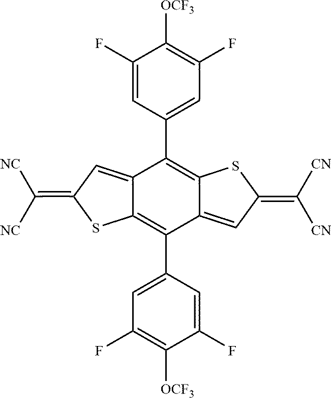

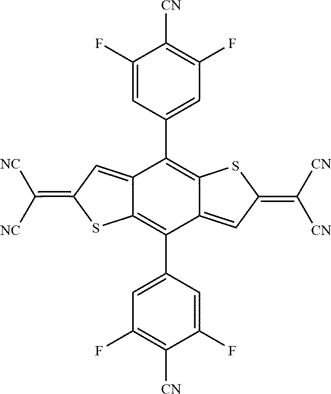

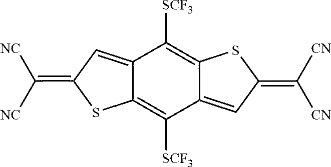

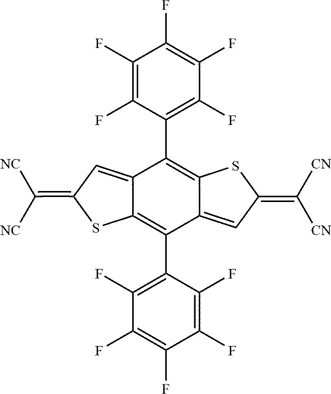

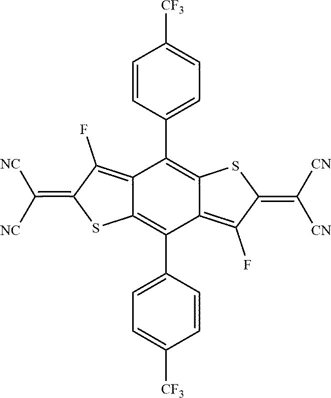

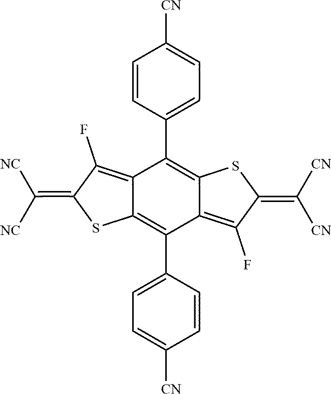

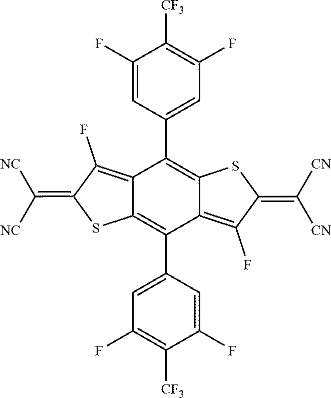

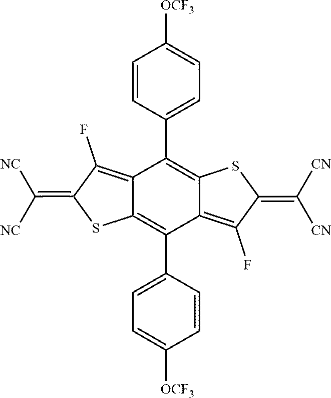

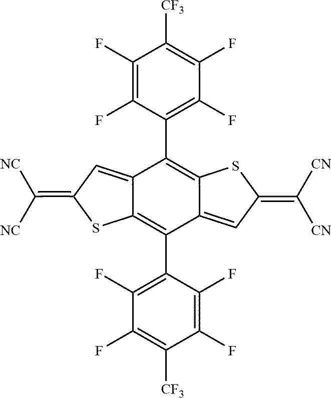

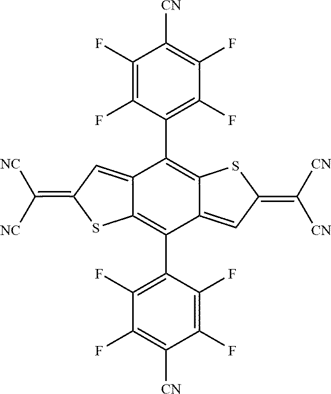

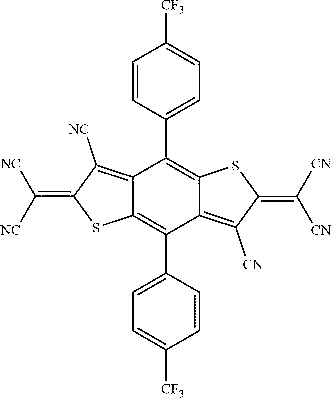

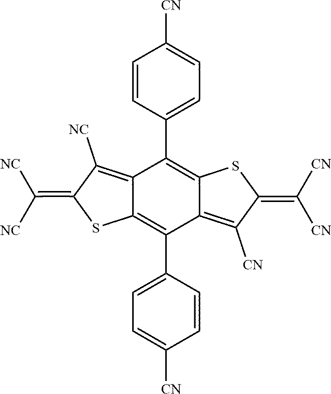

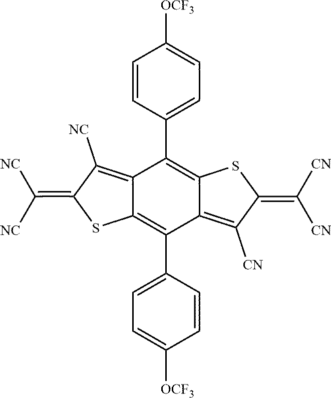

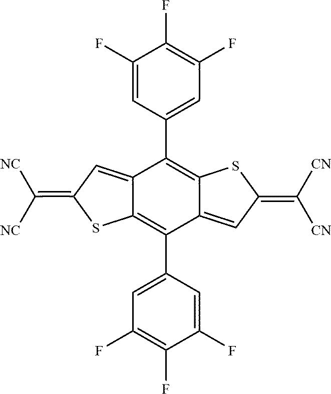

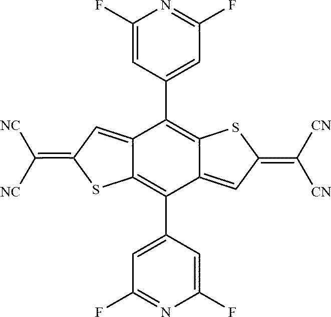

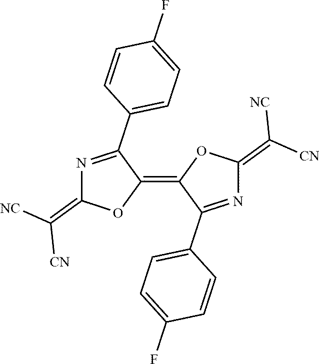

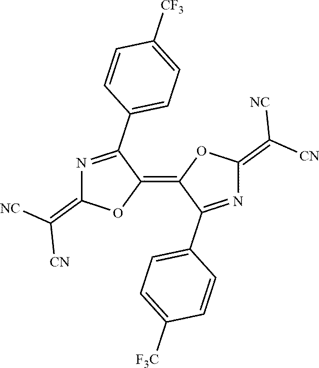

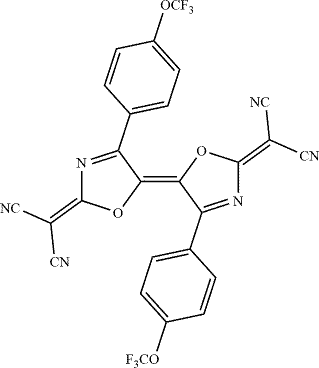

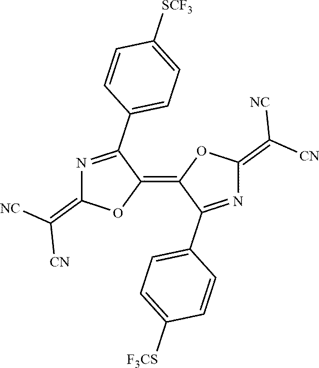

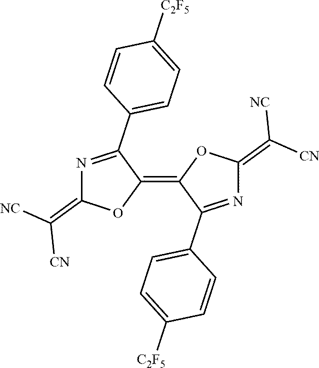

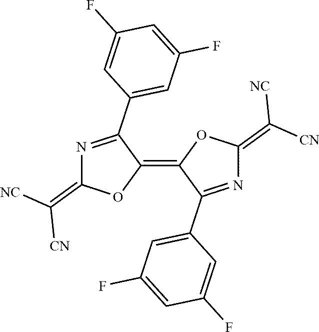

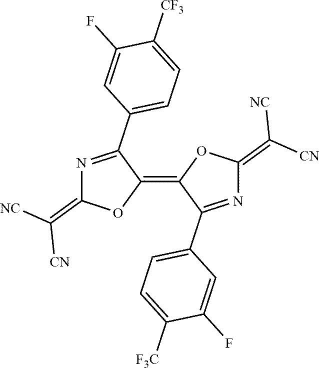

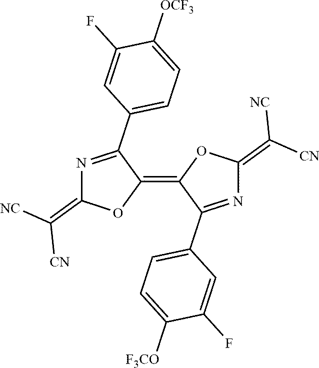

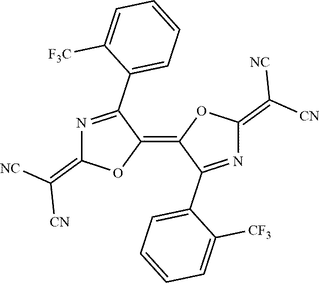

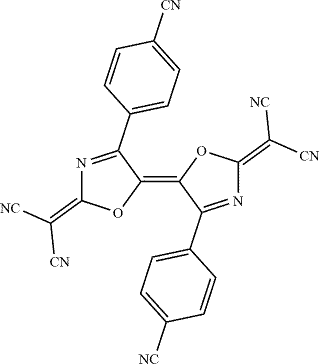

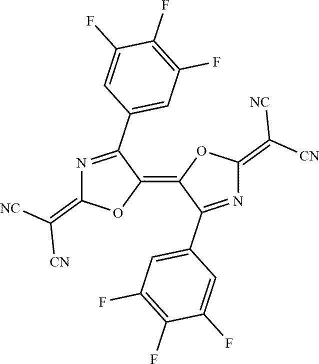

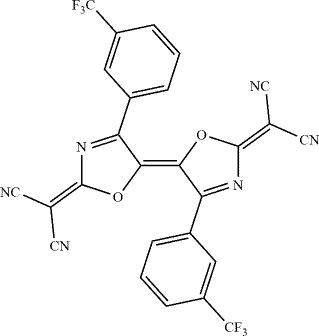

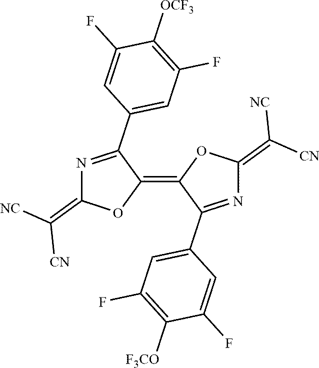

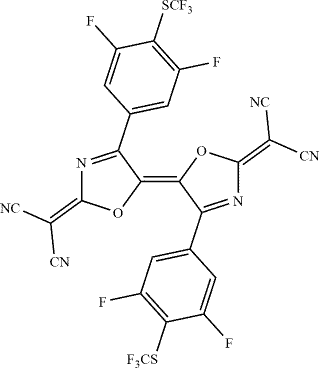

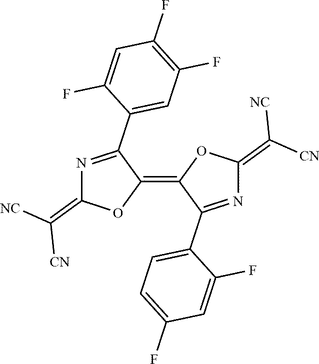

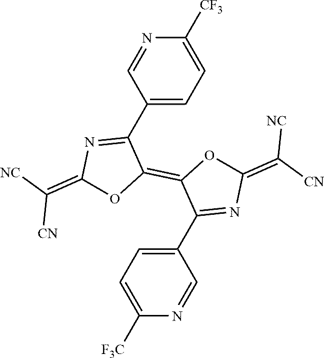

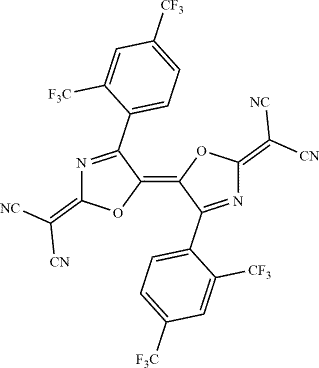

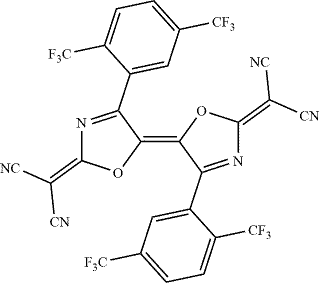

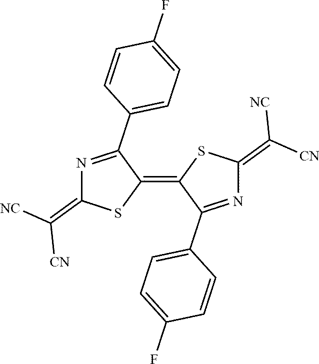

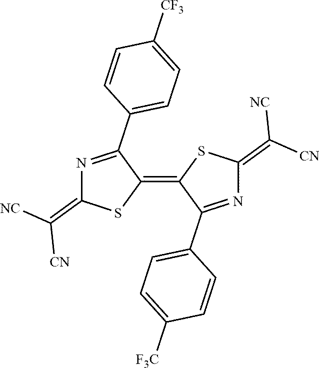

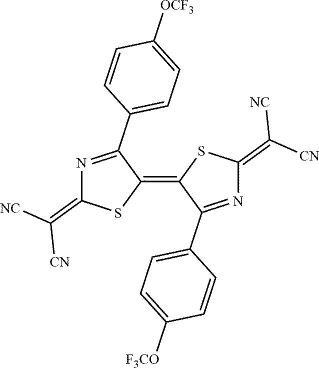

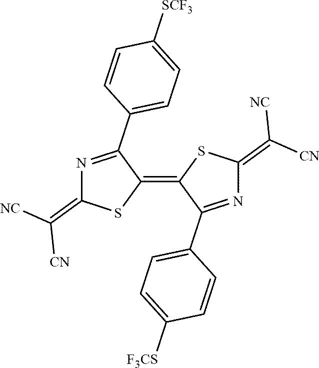

According to an embodiment of the present disclosure, the metal material of the metal layer is selected from the group consisting of: Yb, Li, Rb, Cs, Be, Mg, Ca, Sr, Ba, La, Ce, Pr, Nd, Sm, Eu, Y, Mn, Ag and combinations of the above multiple metals.

According to an embodiment of the present disclosure, the metal material of the metal layer is Yb.

According to an embodiment of the present disclosure, the work function of the metal material of the metal layer is less than 4.0 eV.

According to an embodiment of the present disclosure, the metal layer is formed by one elemental metal, or is formed by two or more elemental metals.

According to an embodiment of the present disclosure, the metal layer has a thickness ranging from 0.1 nm to 20 nm.

According to an embodiment of the present disclosure, the metal layer has a thickness ranging from 0.1 nm to 5 nm .

According to an embodiment of the present disclosure, LUMO_{first organic material} - work functionₘₑₜₐₗ < 2.05 eV.

According to an embodiment of the present disclosure, the first organic layer has a thickness ranging from 0.1 nm to 30 nm.

According to an embodiment of the present disclosure, the first organic layer has a thickness ranging from 0.1 nm to 15 nm.

According to an embodiment of the present disclosure, in the second organic layer, the first organic material accounts for 4% to 49% of the total mass of the second organic layer.

According to an embodiment of the present disclosure, in the second organic layer, the first organic material accounts for 5% to 35% of the total mass of the second organic layer.

According to an embodiment of the present disclosure, in the second organic layer, the first organic material accounts for 5% to 30% of the total mass of the second organic layer.

According to an embodiment of the present disclosure, at least one of the first organic layer and the metal layer forms a discontinuous thin film.

According to an embodiment of the present disclosure, the first organic layer is in direct contact with the second organic layer.

According to an embodiment of the present disclosure, HOMO_{second organic material} -LUMO_{first organic material} ≥ 0.8 eV.

According to an embodiment of the present disclosure, HOMO_{second organic material} -LUMO_{first organic material} ≥ 0.6 eV.

According to an embodiment of the present disclosure, the HOMO energy level of the second organic material is ≥ 5.1 eV.

According to an embodiment of the present disclosure, the visible light transmittance of the connection layer is greater than 70%.

According to an embodiment of the present disclosure, the visible light transmittance of the connection layer is greater than 80%.

According to an embodiment of the present disclosure, the at least two light-emitting units are capable of emitting light of the same color or light of different colors.

According to another embodiment of the present disclosure, an electronic assembly is further disclosed. The electronic assembly comprises an organic electroluminescent device whose specific structure is as shown in any one of the preceding embodiments.

According to an embodiment of the present disclosure, the electronic assembly is a display assembly or an illumination assembly.

The LUMO energy levels and the HOMO energy levels of the materials herein were all tested through the cyclic voltammetry method and taken as absolute values. The test was conducted using an electrochemical workstation modelled CorrTest CS120 produced by WUHAN CORRTEST INSTRUMENTS CORP., LTD and using a three-electrode working system where a platinum disk electrode served as a working electrode, a Ag/AgNO₃ electrode served as a reference electrode, and a platinum wire electrode served as an auxiliary electrode. Anhydrous DCM was used as a solvent, 0.1 mol/L tetrabutylammonium hexafluorophosphate was used as a supporting electrolyte, a compound to be tested was prepared into a solution of 10⁻³ mol/L, and nitrogen was introduced into the solution for 10 min for an oxygen removal before the test. Parameters of the instrument were set as follows: a scan rate of 100 mV/s, a potential interval of 0.5 mV and a test window of -1 V to 1 V.

A work function of the metal material Yb of the connection layer and energy level information of Compound 1-2, Compound PD-2 and the second organic material Compound HT-7 are listed in Table 1.

TABLE 1

Work function of metal material Yb and energy level information of Compound 1-2, Compound PD-2 and Compound HT-7

| | | | | | | | |
|---|---|---|---|---|---|---|---|
| Metal | Work Functionₘₑₜₐₗ | Compound No. | LUMO | Compound No. | HOMO | LUMO - Work Functionₘₑₜₐₗ | HOMO-LUMO |
| Yb | 2.60 eV | 1-2 | 4.63 eV | HT-7 | 5.13 eV | 2.03 eV | 0.50 eV |
| Yb | 2.60 eV | PD-2 | 4.91 eV | HT-7 | 5.13 eV | 2.31 eV | 0.22 eV |

Specific structures of Compound 1-2, Compound PD-2 and Compound HT-7 are as follows:

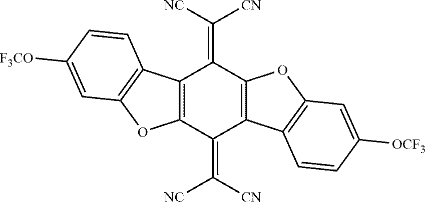

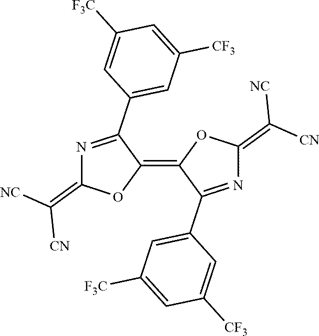

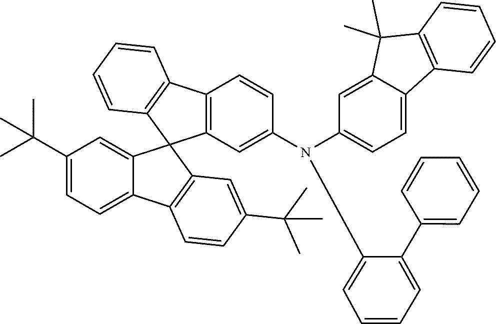 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

Specifically, a metal used in device examples of the present disclosure is Yb shown in Table 1, where the work function of Yb is relatively small, which is 2.6 eV. To satisfy LUMO_{first organic material} - work functionₘₑₜₐₗ ≤ 2.1 eV, the LUMO energy level of the first organic material should satisfy LUMO_{first organic material} ≤ 4.7 eV. In the examples herein, Compound 1-2, whose LUMO energy level is less than 4.7 eV, is preferred as the first organic material, where the LUMO energy level of Compound 1-2 is 4.63 eV, Compound HT-7, whose HOMO energy level is ≥ 5.1 eV, is preferred as the second organic material, and in this case, LUMO_{Compound} 1-2 -work function_{Yb} = 2.03 eV, which is less than 2.1 eV. An electron injection ability is improved through an adjustment of the difference between the work function of the metal material of the metal layer and the LUMO energy level of the first organic material of the first organic layer, improving the device efficiency. When HOMO_{second organic material} — LUMO_{first organic material} ≥ 0.3 eV, an adjustment space is provided for hole injection, which is convenient to control a hole injection level, achieve a balance of carriers and improve exciton recombination efficiency. For example, in the device examples of the present disclosure, the first organic material Compound 1-2 is selected as the dopant and co-evaporated with the second organic material Compound HT-7 to form the second organic layer, and HOMO_{HT-7} - LUMO_{Compound} 1-2 = 0.5 eV, which is greater than 0.3 eV. When a doping concentration is 16 wt%, better device performance is obtained.

In the present disclosure, Compound PD-2 is selected as a material of the connection layer in comparative examples. A LUMO energy level of Compound PD-2 is 4.91 eV, and HOMO_{HT-7} - LUMO_{Compound PD-2} = 0.22 eV. When a doping concentration of Compound PD-2 is 3 wt%, although the low-concentration doping ensures an injection of holes, since the first organic material having a relatively deep energy level is used, the difference between the LUMO of the first organic material and the work function of the metal is relatively large (LUMO_{HT-7} - work function_{Yb} = 2.31 eV, which is greater than 2.1 eV), which is not conductive to a separation and injection of electrons and impedes the improvement of the device efficiency.

The present applicant’s previous application CN202110131806.4 records a stacked organic electroluminescent device which adopts metal Yb as a metal layer of a charge generation layer and Compound 1-70

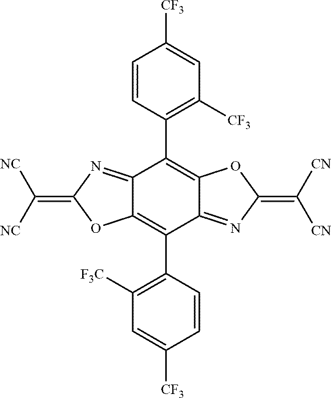

as a buffer layer (a first organic layer) of the charge generation layer and records that a LUMO energy level of Compound 1-70 is 5.69 eV. Therefore, in the stacked device disclosed in the application, LUMO_{Compound}₁₋₇₀ -work function_{Yb} = 3.09 eV, which is much greater than 2.1 eV and different from LUMO_{first organic material} - work functionₘₑₜₐₗ ≤ 2.1 eV required in the technical solution as claimed in the present application, belonging to different inventive concepts.

Hereinafter, the present disclosure is described in more detail with reference to the following examples. Apparently, the following examples are only for the purpose of illustration and not intended to limit the scope of the present disclosure. Based on the following examples, those skilled in the art can obtain other examples of the present disclosure by conducting improvements on these examples.

### Device Example

Example 1: a tandem organic electroluminescent device 100 comprising the connection layer of the present disclosure was prepared, as shown in FIG. 1.

First, a glass substrate 110 which was previously coated with a patterned indium tin oxide (ITO) anode 120 with a thickness of 1200 Å was cleaned with ultrapure water, and an ITO surface was treated with UV ozone and oxygen plasma. The substrate was dried in a nitrogen-filled glove box to remove moisture, then mounted on a support and placed in an evaporation chamber. The organic layers specified below were sequentially coated through thermal evaporation on the ITO anode at a rate of 0.01 to 10 Å/s at a vacuum degree of about 1* 10⁻⁶ torr. First, a first light-emitting unit 110a was evaporated, including that Compound HT-7 and Compound 1-2 were co-evaporated to form a hole injection layer 111a, where Compound 1-2 accounted for 16% of a weight of the hole injection layer (HIL) 111a, and the HIL had a thickness of 100 Å. Compound HT-7 was evaporated as a hole transporting layer (HTL) 112a with a thickness of 200 Å. Compound H-1 was evaporated for use as an electron blocking layer (EBL) 113a with a thickness of 50 Å. A red dopant Compound D-1 and a red host compound H-2 were co-deposited for use as a light-emitting layer (EML) 114a, where a doping concentration was 3 wt%, and the EML had a thickness of 400 Å. On the light-emitting layer, Compound H-3 was evaporated as a hole blocking layer (HBL) 115a with a thickness of 50 Å. On the HBL, Compound ET and Compound EI were co-deposited as an electron transporting layer (ETL) 116a, where Compound EI accounted for 60% of a total weight of the ETL, and the ETL had a thickness of 350 Å. After that, sequentially, metal Yb with a thickness of 15 Å was evaporated as a metal layer 130a of a connection layer 130, and Compound 1-2 with a thickness of 30 Å was evaporated as a first organic layer 130b of the connection layer 130. Next, a second light-emitting unit 110b was evaporated, including that Compound HT-7 and Compound 1-2 were co-evaporated to form a second organic layer (a hole injection layer) 111b, where Compound 1-2 accounted for 16% of a total weight of the second organic layer (the hole injection layer 111b), and the HIL had a thickness of 100 Å. Subsequently, Compound HT-7 with a thickness of 1000 Å was evaporated as a hole transporting layer 112b. Compound H-1 was used as an electron blocking layer (EBL) 113b with a thickness of 50 Å. The red dopant Compound D-1 and the red host compound H-2 were co-deposited for use as a light-emitting layer (EML) 114b, where a doping concentration was 3 wt%, and a total thickness was 400 Å. Compound H-3 was used as a hole blocking layer (HBL) 115b and evaporated on the light-emitting layer with a thickness of 50 Å. On the HBL, Compound ET and Compound EI were co-deposited as an electron transporting layer (ETL) 116b, where Compound EI accounted for 60% of a total weight of the ETL, and the ETL had a total thickness of 350 Å. Finally, Compound EI with a thickness of 10 Å was evaporated as an electron injection layer (EIL) 117b, and aluminum with a thickness of 1200 Å was evaporated as a cathode 140.

Note that the above device structure is only for illustrative and is not limited to the description of the present disclosure. For example, the hole injection layer 111a in the first light-emitting unit 110a may use a different structure from the hole injection layer 111b in the second light-emitting unit 110b, and vice versa. For another example, the second light-emitting unit 110b may use host compounds of other colors and light-emitting materials as well as corresponding matched transporting materials and device structures. After the device was prepared, the device was transferred from the evaporation chamber back to the glove box and packaged with a glass cover.

Example 2: a preparation method of Example 2 was the same as that of Example 1, except that in the first light-emitting unit, Compound HT-7 and Compound 1-2 were co-evaporated to form a hole injection layer (HIL, weight ratio 80:20, 100 Å) to replace the hole injection layer in the first light-emitting unit in Example 1.

Comparative Example 1: a preparation method of Comparative Example 1 was the same as that of Example 1, only except that: (1) in the first light-emitting unit, Compound HT-7 and Compound PD-2 were co-evaporated to form a hole injection layer (HIL, weight ratio 97:3, 100 Å) to replace the hole injection layer in the first light-emitting unit in Example 1; (2) in the connection layer, Compound PD-2 with a thickness of 30 Å was evaporated to form a first organic layer to replace the first organic layer in the connection layer in Example 1; and (3) in the second light-emitting unit, Compound HT-7 and Compound PD-2 were co-evaporated to form a hole injection layer (HIL, weight ratio 97:3, 100 Å) to replace the hole injection layer in the second light-emitting unit in Example 1.

Comparative Example 2: a preparation method of Comparative Example 2 was the same as that of Comparative Example 1, only except that: (1) in the first light-emitting unit, Compound HT-7 and Compound PD-2 were co-evaporated to form a hole injection layer (HIL, weight ratio 84:16, total thickness 100 Å) to replace the hole injection layer in the first light-emitting unit in Comparative Example 1; and (2) in the second light-emitting unit, Compound HT-7 and Compound PD-2 were co-evaporated to form a hole injection layer (HIL, weight ratio 84:16, total thickness 100 Å) to replace the hole injection layer in the second light-emitting unit in Comparative Example 1.

Comparative Example 3: a preparation method of Comparative Example 3 was the same as that of Example 1, only except that: (1) in the connection layer, Compound PD-2 with a thickness of 30 Å was evaporated to form a first organic layer to replace the first organic layer in the connection layer in Example 1; and (2) in the second light-emitting unit, Compound HT-7 and Compound PD-2 were co-evaporated to form a hole injection layer (HIL, weight ratio 84:16, 100 Å) to replace the hole injection layer in the second light-emitting unit in Example 1.

Comparative Example 4: a red light monolayer organic electroluminescent device 200 was prepared, as shown in FIG. 2 (as a schematic illustration, this figure does not include a substrate layer).

First, a glass substrate which was previously coated with a patterned indium tin oxide (ITO) anode 220 with a thickness of 1200 Å was cleaned with ultrapure water, and an ITO surface was treated with UV ozone and oxygen plasma. The substrate was dried in a nitrogen-filled glove box to remove moisture, then mounted on a support and placed in an evaporation chamber. The organic layers specified below were sequentially coated through thermal evaporation on the ITO anode 220 at a rate of 0.01 to 10 Å/s at a vacuum degree of about 1*10⁻⁶ torr. Compound HT-7 and Compound 1-2 were co-evaporated to form a hole injection layer (HIL) 211, where Compound 1-2 accounted for 16% of a weight of the hole injection layer (HIL) 211, and the HIL had a total thickness of 100 Å. Compound HT-7 was used as a hole transporting layer (HTL) 212 with a thickness of 200 Å. Compound H-1 was used as an electron blocking layer (EBL) 213 with a thickness of 50 Å. A red dopant Compound D-1 and a red host compound H-2 were co-deposited for use as a light-emitting layer (EML) 214, where a doping concentration was 3 wt%, and a total thickness was 400 Å. Compound H-3 was used as a hole blocking layer (HBL) 215 and evaporated on the light-emitting layer with a thickness of 50 Å. On the HBL, Compound ET and Compound EI were co-deposited as an electron transporting layer (ETL) 216, where Compound EI accounted for 60% of a total weight of the ETL, and the ETL had a total thickness of 350 Å. Finally, Compound EI with a thickness of 10 Å was evaporated as an electron injection layer (EIL) 217, and aluminum with a thickness of 1200 Å was evaporated as a cathode 230.

Comparative Example 5: a red light monolayer organic electroluminescent device 300 was prepared through the same preparation method as that of Comparative Example 4 (the monolayer device 200), only except that Compound PD-2 and Compound HT-7 were co-evaporated to form a hole injection layer, where Compound PD-2 accounted for 16% of a weight of the hole injection layer, and a thickness was 100 Å.

Comparative Example 6: a red light monolayer organic electroluminescent device 400 was prepared through the same preparation method as that of Comparative Example 5 (the monolayer device 300), only except that Compound PD-2 and Compound HT-7 were co-evaporated to form a hole injection layer, where Compound PD-2 accounted for 3% of a weight of the hole injection layer, and a thickness was 100 Å.

Detailed structures and thicknesses of part of organic layers of the devices are shown in Table 2 below. A layer using more than one material is obtained by doping different compounds at their weight ratio as recorded.

TABLE 2

Part of device structures in Examples 1 and 2 and Comparative Examples 1 to 6

| Device No. | First Light-emitting Unit | | Connection Layer | | Second Light-emitting Unit | |
|---|---|---|---|---|---|---|
| | HIL | HTL | Metal Layer | First Organic Layer | HIL | HTL |
| Example 1 | HT-7:1-2 (84:16) (100 Å) | HT-7 (200 Å) | Yb (15 Å) | 1-2 (30 Å) | HT-7:1-2 (84:16) (100 Å) | HT-7 (1000 Å) |
| Example 2 | HT-7:1-2 (80:20) (100 Å) | HT-7 (200 Å) | Yb (15 Å) | 1-2 (30 Å) | HT-7:1-2 (84:16) (100 Å) | HT-7 (1000 Å) |
| Comparat ive Example 1 | HT-7:PD-2 (97:3) (100 Å) | HT-7 (200 Å) | Yb (15 Å) | PD-2 (30 Å) | HT-7:PD-2 (97:3)(100 Å) | HT-7 (1000 Å) |
| Comparat ive Example 2 | HT-7:PD-2 (84:16) (100 Å) | HT-7 (200 Å) | Yb (15 Å) | PD-2 (30 Å) | HT-7:PD-2 (84:16)(100 Å) | HT-7 (1000 Å) |
| Comparat ive Example 3 | HT-7:1-2 (84:16) (100 Å) | HT-7 (200 Å) | Yb (15 Å) | PD-2 (30 Å) | HT-7:PD-2 (84:16)(100 Å) | HT-7 (1000 Å) |
| Comparat ive Example 4 | HT-7:1-2 (84:16) (100 Å) | HT-7 (200 Å) | - | - | - | - |
| Comparat ive Example 5 | HT-7:PD-2 (84:16) (100 Å) | HT-7 (200 Å) | - | - | - | - |
| Comparat ive Example 6 | HT-7:PD-2 (97:3) (100 Å) | HT-7 (200 Å) | - | - | - | - |

Structures of Compound 1-2, Compound PD-2, Compound HT-7, Compound H-1, Compound H-2, Compound D-1, Compound H-3, Compound ET and Compound EI are as follows:

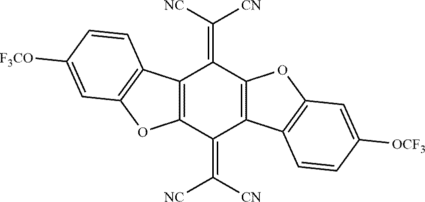

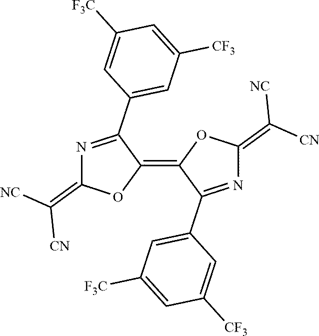

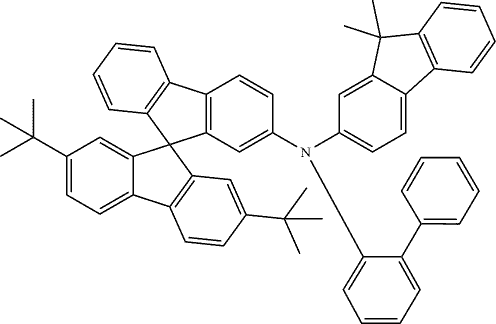 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

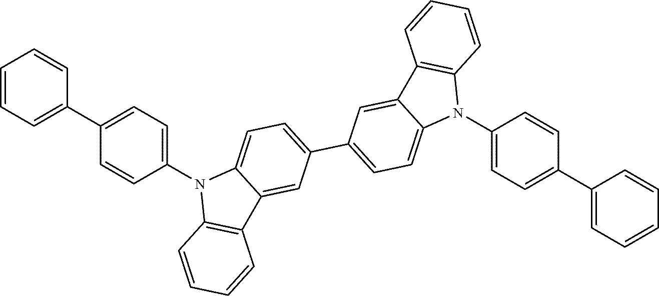 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

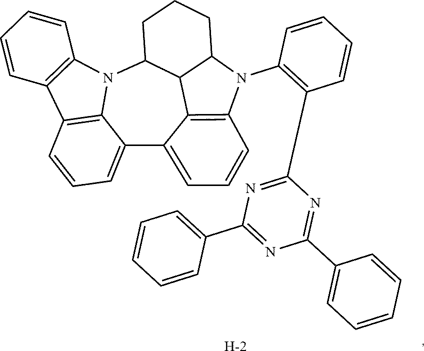

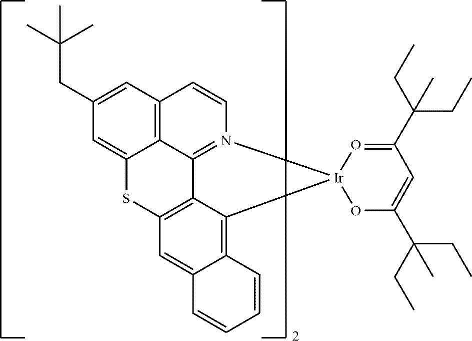

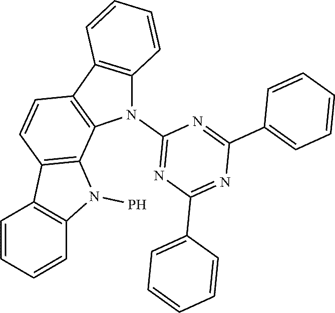

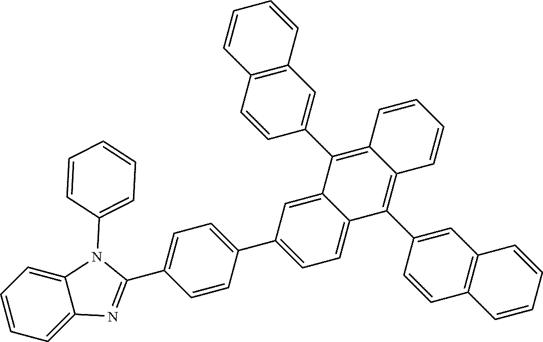 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

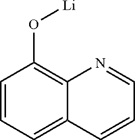

The performance test results of Examples 1 and 2 and Comparative Examples 1 to 6 are listed in Table 3, where the chromaticity coordinates, the power efficiency, the external quantum efficiency and the voltages are measured at a brightness of 2000 cd/m², and the device lifetime is the time for the device brightness to decay to 97% of the initial brightness of 2000 cd/m².

TABLE 3

Device performance in Examples 1 and 2 and Comparative Examples 1 to 6

| Device No. | Chromaticity Coordinate (x,y) | Lifetime (h) | Power Efficiency (lm/W) | External Quantum Efficiency (%) | Voltage (V) |
|---|---|---|---|---|---|
| Example 1 | (0.702, 0.298) | 37727 | 24.7 | 69 | 6.3 |
| Example 2 | (0.702, 0.298) | 50913 | 23.7 | 62 | 6.1 |
| Comparative Example 1 | (0.702, 0.298) | 37000 | 21.8 | 58 | 6.1 |
| Comparative Example 2 | (0.702, 0.298) | 33221 | 20.5 | 55 | 6.1 |
| Comparative Example 3 | (0.701, 0.298) | 38000 | 22.0 | 57 | 6.2 |
| Comparative Example 4 | (0.701, 0.298) | 7500 | 17.0 | 30 | 3.8 |
| Comparative Example 5 | (0.700, 0.299) | 8000 | 17.0 | 25 | 3.4 |
| Comparative Example 6 | (0.701, 0.299) | 9300 | 18.0 | 26 | 3.3 |

The chromaticity coordinates of Examples 1 and 2 and Comparative Examples 1 to 6 are substantially the same, indicating that the first organic material of the connection layer does not affect the color of the device itself.

As can be seen from the device performance data recorded in Table 3, compared with Comparative Example 5 (the monolayer device 300), the external quantum efficiency of Comparative Example 4 (the monolayer device 200) is increased by 20%, the voltage is also increased by 0.4 V, and due to the increase in voltage, the power efficiency of the monolayer device 200 and the monolayer device 300 at the same brightness of 2000 cd/m² is the same, which is 17 lm/W. The monolayer device 200 differs from the monolayer device 300 in that the doped material used in the hole injection layer is different. In the hole injection layer of the monolayer device 200, HOMO_{HT-7} - LUMO_{Compound} 1-2 = 0.5 eV, and in the hole injection layer of the monolayer device 300, HOMO_{HT-7} - LUMO_{Compound PD-2} = 0.22 eV. It can be seen that the large energy level difference between Compound HT-7 and Compound 1-2 in the hole injection layer of the monolayer device 200 makes a hole injection difficult, and although the efficiency of the monolayer device 200 is improved by 20% compared with that of the monolayer device 300, the voltage is also increased, and the device lifetime is also slightly reduced by 6%.

However, in the stacked device, it can be seen from the comparison of the device performance between Example 1 and Comparative Example 4 (the monolayer device 200) that the external quantum efficiency of Example 1 is 2.3 times that of Comparative Example 4 (the monolayer device 200), and the lifetime is 5.03 times that of the monolayer device 200. However, in Example 1, the voltage is 6.3 V, which is only 1.65 times that of the device 200, and the power efficiency is improved by 45% compared with that of the device 200. Therefore, although compared with the monolayer device 300, the monolayer device 200 has a problem of high voltage, but this phenomenon does not exist in the stacked device in Example 1. This indicates that in the connection layer, a difference between a work function of the metal material and a LUMO energy level of the first organic material has a very great effect on the voltage of the tandem device. In the connection layer in Example 1 of the present disclosure, LUMO_{Compound} 1-2 - work function_{Yb} = 2.03 eV, which indicates that the difference between LUMO_{first organic material} and work functionₘₑₜₐₗ of the connection layer of the tandem device is controlled to be less than 2.1 eV, preferably less than 2.05 eV, which can promote a separation of electrons at metal and organic interfaces, suppressing a recombination of carriers at the interfaces and improving overall performance of the device.

As can be seen from the comparison between Example 1 and Comparative Example 3, in Example 1, Yb is used in the metal layer in the connection layer, Compound 1-2 is used in the first organic layer, and LUMO_{Compound}₁₋₂ - work function_{Yb} = 2.03 eV; Compound HT-7 and Compound 1-2 are used in the second organic layer, and HOMO_{HT-7} - LUMO_{Compound}₁₋₂ = 0.5 eV; while in Comparative Example 3, Yb is used in the metal layer in the connection layer, Compound PD-2 is used in the first organic layer, and LUMO_{Compound PD-2} - work function_{Yb} = 2.31 eV, which is greater than 2.1 eV; Compound HT-7 and Compound PD-2 are used in the second organic layer, and HOMO_{HT-7} - LUMO_{Compound PD-2} = 0.22 eV, which is less than 0.3 eV. As can be seen from the device performance data in Table 3, compared with Comparative Example 3, Example 1 achieves a 21% significant improvement in external quantum efficiency while maintaining substantially the same lifetime, and the power efficiency is also improved by 12%. It can be seen that through an adjustment of the difference between the HOMO energy level of the second organic material and the LUMO energy level of the first organic material of the hole injection layer (the second organic layer) in contact with the connection layer, HOMO_{second organic material} — LUMO_{first organic material} ≥ 0.3 eV, and the hole injection of the device can be controlled. At the same time, the difference between the energy level of LUMO_{first organic material} and work functionₘₑₜₐₗ is reduced so that LUMO_{first organic material} - work functionₘₑₜₐₗ ≤ 2.1 eV, which can improve an electron injection ability of the device, improving the overall performance of the tandem device, such as obtaining higher external quantum efficiency and power efficiency.

It can be seen from the comparison of the performance data between the stacked device in Comparative Example 2 and Comparative Example 5 (the monolayer device 300) that the external quantum efficiency of Comparative Example 2 is 2.2 times that of Comparative Example 5 (the monolayer device 300), the lifetime is 4.15 times that of the monolayer device 300 and the voltage is only 1.79 times that of the monolayer device 300. This indicates that the overall performance of the stacked device in Comparative Example 2 has been significantly improved compared with that of the monolayer device 300.

It can be seen from the comparison of the performance data between Comparative Example 5 (the monolayer device 300) and Comparative Example 6 (the monolayer device 400) that the voltage of the monolayer device 400 is lower compared with that of the monolayer device 300 and both the external quantum efficiency and the power efficiency are improved. It can be seen that when the doping concentration of Compound PD-2 in the HIL is 3 wt%, the overall performance of the device is better. On this basis, the stacked device in Comparative Example 2 is further optimized to obtain Comparative Example 1, that is, the doping concentration of Compound PD-2 in the HIL is 3 wt%. As can be seen from the data recorded in Table 3, compared with Comparative Example 2, the device voltage of Comparative Example 1 is maintained at 6.1 V, and the external quantum efficiency and the lifetime are increased by 5% and 11%, respectively; moreover, compared with Comparative Example 6 (the monolayer device 400), the external quantum efficiency of Comparative Example 1 is 2.2 times that of the monolayer device 400, the lifetime is 4.0 times that of the monolayer device 400, and the voltage is only 1.8 times that of the monolayer device 400, indicating that Comparative Example 1 is already a stacked device with better overall performance.

However, compared with Comparative Example 1 where the doping proportion of Compound PD-2 has been optimized, Example 1 still achieves a 19% improvement in external quantum efficiency and a 13% improvement in power efficiency while the lifetime and the voltage are substantially the same. As can be seen from the comparison of the device structures between Example 1 and Comparative Example 1, Compound 1-2 and Compound PD-2 are used as the first organic materials in Example 1 and Comparative Example 1, respectively; in Example 1, in the second organic layer, HOMO_{HT-7} - LUMO_{Compound}₁₋₂ = 0.5 eV, which is greater than 0.3 eV, and in the connection layer, LUMO_{Compound}₁₋₂ - work function_{yb} = 2.03 eV, which is less than 2.1 eV; while in Comparative Example 1, in the second organic layer, HOMO_{HT-7} - LUMO_{Compound}_{PD-2} = 0.22 eV, which is less than 0.3 eV, and in the connection layer, LUMO_{CompoundPD-2} - work function_{Yb} = 2.31 eV, which is greater than 2.1 eV This again proves that when the difference between the energy level of LUMO_{first organic material} and work functionₘₑₜₐₗ is reduced so that LUMO_{first organic material} - work functionₘₑₜₐₗ ≤ 2.1 eV and HOMO_{second organic material} - LUMO_{first organic material} is controlled to be ≥ 0.3 eV, the overall performance of the stacked device can be further improved and higher external quantum efficiency and higher power efficiency can be obtained.

In the stacked device disclosed in the present application, the hole injection layer in contact with the anode may be consistent or inconsistent with the hole injection layer (the second organic layer) in contact with the connection layer in structure. For example, the doped material and the doping concentration used in the hole injection layer of the first light-emitting unit may be the same as or different from those used in the hole injection layer (the second organic layer) of the second light-emitting unit. However, the doped material used in the first organic layer in the connection layer must be the same as that used in the second organic layer. For example, in Example 2, the doping concentration of Compound 1-2 in the HIL of the first light-emitting unit is 20 wt%, and the concentration of Compound 1-2 in the second organic layer is 16%. That is, on the basis of Example 1, Example 2 further improves the doping concentration of Compound 1-2 in the HIL of the first light-emitting unit. Although the external quantum efficiency of Example 2 is reduced by 11% while maintaining the same voltage, a relatively high level of 62% is achieved, and Example 2 further achieves a significant 35% improvement in lifetime compared with Example 1. It can be seen that an adjustment of hole injection in the HIL in contact with the anode can balance the carriers, thereby balancing the efficiency, lifetime and voltage of the device.

In conclusion, the tandem organic electroluminescent device comprising multiple light-emitting units, the second organic layer and the specific connection layer disclosed in the present disclosure satisfies LUMO_{first organic material} - work functionₘₑₜₐₗ ≤ 2.1 eV, which can promote the separation of the electrons at the metal and organic interfaces, suppressing the recombination of the carriers at the interfaces; HOMO_{second organic material} - LUMO_{first organic material} is controlled to be ≥ 0.3 V, and the hole injection is controlled through the adjustment of the doping concentration of the first organic material, which can balance a recombination of the carriers on the light-emitting layer, significantly improving the efficiency and lifetime of the device and reducing power consumption of the device. This new tandem organic electroluminescent device has more excellent device performance and broader application prospects.

It is to be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limitative.

What is claimed is:

1. An organic electroluminescent device, comprising:
a first electrode,
a second electrode, and
at least two light-emitting units disposed between the first electrode and the second electrode,
wherein a connection layer is further disposed between the at least two light-emitting units, and the connection layer comprises a metal layer and a first organic layer, wherein the first organic layer comprises a first organic material whose LUMO energy level is LUMO_{first organic material}, and the metal layer comprises at least one metal material whose work function is work functionₘₑₜₐₗ, wherein LUMO_{first organic material} - work functionₘₑₜₐₗ ≤ 2.1 eV; and
the light-emitting unit in contact with the first organic layer further comprises a second organic layer, wherein the second organic layer comprises a second organic material and the first organic material, wherein a HOMO energy level of the second organic material is HOMO_{second organic material}, and HOMO_{second organic material} - LUMO_{first organic material} ≥ 0.3 eV.

2. The organic electroluminescent device according to claim 1, wherein the LUMO energy level of the first organic material is ≤ 4.7 eV.

3. The organic electroluminescent device according to claim 1, wherein the first organic material has a structure represented by one of Formula 1 to Formula 3: 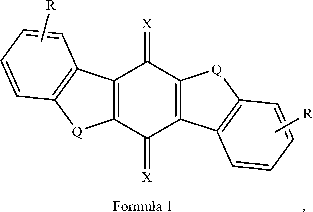 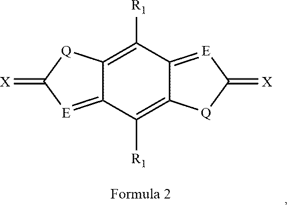 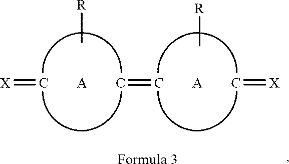
wherein in Formula 1, Formula 2 or Formula 3,
E is, at each occurrence identically or differently, selected from CR₁;
X is, at each occurrence identically or differently, selected from the group consisting of NR′, CR″R‴, O, S and Se;
the ring A is, at each occurrence identically or differently, a five-membered heterocyclic ring containing one intracyclic double bond, at least one N atom and at least one Q;
Q is, at each occurrence identically or differently, selected from the group consisting of O, S, Se and NR_{N};
R represents, at each occurrence identically or differently, mono-substitution, multiple substitutions or non-substitution;
R, R₁, R′, R″, R‴ and R_{N} are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof;
at least one of substituents R, R₁, R′, R″ and R‴ is a group having at least one electron-withdrawing group;
adjacent substituents R, R′, R″, R‴ can be optionally joined to form a ring; and
preferably, the first organic material has a structure represented by Formula 1 or Formula 2.

4. The organic electroluminescent device according to claim 3, wherein X is, at each occurrence identically or differently, selected from CR″R‴ or NR′, and each of R′, R″ and R‴ is a group having at least one electron-withdrawing group; and
preferably, each of R, R′, R″ and R‴ is a group having at least one electron-withdrawing group.

5. The organic electroluminescent device according to claim 3, wherein X is, at each occurrence identically or differently, selected from the group consisting of the following structures: 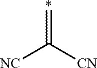 [SMILES: *=C(C#N)C#N] 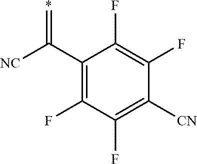 [SMILES: *=C(C#N)c1c(F)c(F)c(C#N)c(F)c1F] 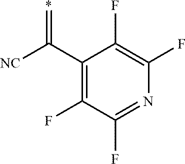 [SMILES: *=C(C#N)c1c(F)c(F)nc(F)c1F] 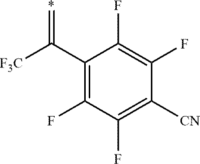 [SMILES: *=C(c1c(F)c(F)c(C#N)c(F)c1F)C(F)(F)F] 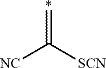 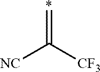 [SMILES: *=C(C#N)C(F)(F)F] 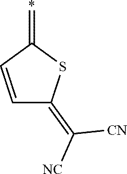 [SMILES: *=c1ccc(=C(C#N)C#N)s1]
; preferably, X is selected from X-1.

6. The organic electroluminescent device according to claim 1, wherein the first organic material is selected from the group consisting of the following structures: 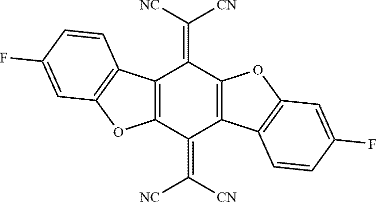 [SMILES: N#CC(C#N)=c1c2oc3cc(F)ccc3c2c(=C(C#N)C#N)c2oc3cc(F)ccc3c12] 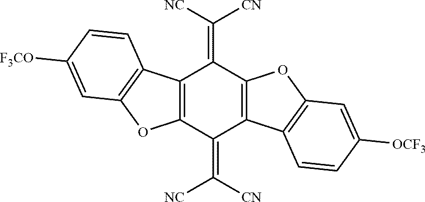 [SMILES: N#CC(C#N)=c1c2oc3cc(OC(F)(F)F)ccc3c2c(=C(C#N)C#N)c2oc3cc(OC(F)(F)F)ccc3c12] 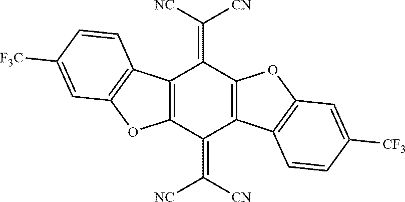 [SMILES: N#CC(C#N)=c1c2oc3cc(C(F)(F)F)ccc3c2c(=C(C#N)C#N)c2oc3cc(C(F)(F)F)ccc3c12] 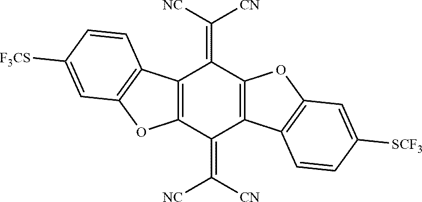 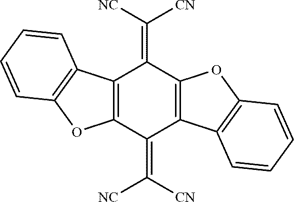 [SMILES: N#CC(C#N)=c1c2oc3ccccc3c2c(=C(C#N)C#N)c2oc3ccccc3c12] 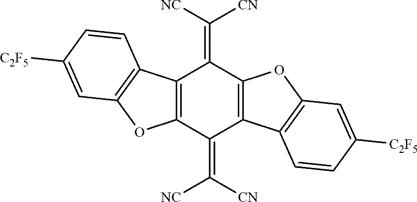 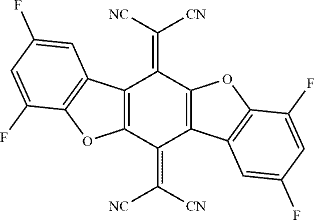 [SMILES: N#CC(C#N)=c1c2oc3c(F)cc(F)cc3c2c(=C(C#N)C#N)c2oc3c(F)cc(F)cc3c12] 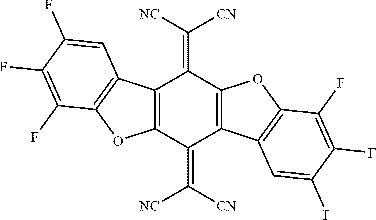 [SMILES: N#CC(C#N)=c1c2oc3c(F)c(F)c(F)cc3c2c(=C(C#N)C#N)c2oc3c(F)c(F)c(F)cc3c12] 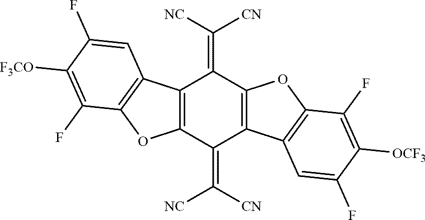 [SMILES: N#CC(C#N)=c1c2oc3c(F)c(OC(F)(F)F)c(F)cc3c2c(=C(C#N)C#N)c2oc3c(F)c(OC(F)(F)F)c(F)cc3c12] 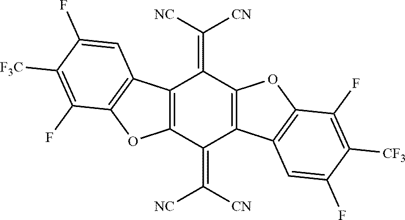 [SMILES: N#CC(C#N)=c1c2oc3c(F)c(C(F)(F)F)c(F)cc3c2c(=C(C#N)C#N)c2oc3c(F)c(C(F)(F)F)c(F)cc3c12] 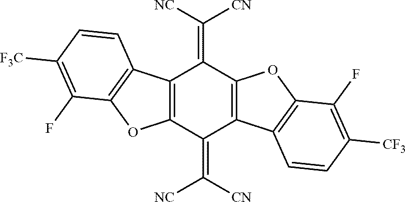 [SMILES: N#CC(C#N)=c1c2oc3c(F)c(C(F)(F)F)ccc3c2c(=C(C#N)C#N)c2oc3c(F)c(C(F)(F)F)ccc3c12] 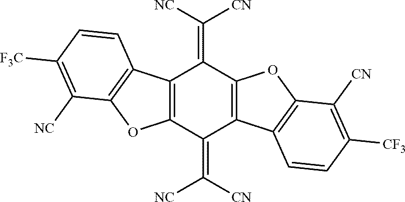 [SMILES: N#CC(C#N)=c1c2oc3c(C#N)c(C(F)(F)F)ccc3c2c(=C(C#N)C#N)c2oc3c(C#N)c(C(F)(F)F)ccc3c12] 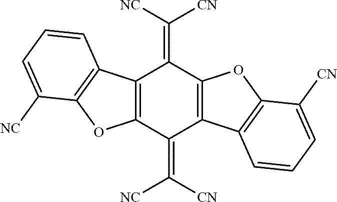 [SMILES: N#CC(C#N)=c1c2oc3c(C#N)cccc3c2c(=C(C#N)C#N)c2oc3c(C#N)cccc3c12] 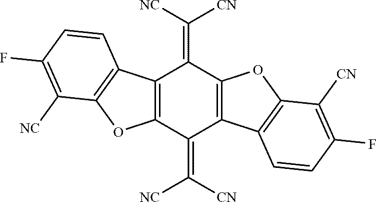 [SMILES: N#CC(C#N)=c1c2oc3c(C#N)c(F)ccc3c2c(=C(C#N)C#N)c2oc3c(C#N)c(F)ccc3c12] 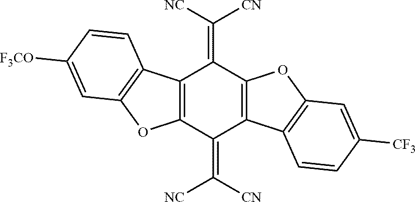 [SMILES: N#CC(C#N)=c1c2oc3cc(C(F)(F)F)ccc3c2c(=C(C#N)C#N)c2oc3cc(OC(F)(F)F)ccc3c12] 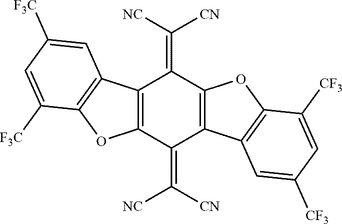 [SMILES: N#CC(C#N)=c1c2oc3c(C(F)(F)F)cc(C(F)(F)F)cc3c2c(=C(C#N)C#N)c2oc3c(C(F)(F)F)cc(C(F)(F)F)cc3c12] 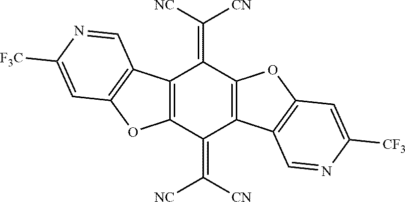 [SMILES: N#CC(C#N)=c1c2oc3cc(C(F)(F)F)ncc3c2c(=C(C#N)C#N)c2oc3cc(C(F)(F)F)ncc3c12] 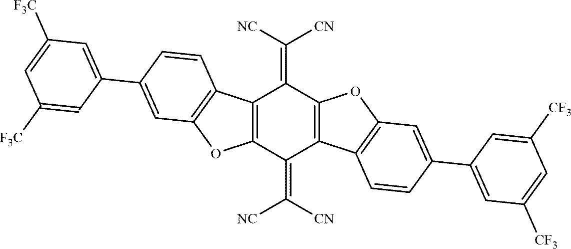 [SMILES: N#CC(C#N)=c1c2oc3cc(-c4cc(C(F)(F)F)cc(C(F)(F)F)c4)ccc3c2c(=C(C#N)C#N)c2oc3cc(-c4cc(C(F)(F)F)cc(C(F)(F)F)c4)ccc3c12] 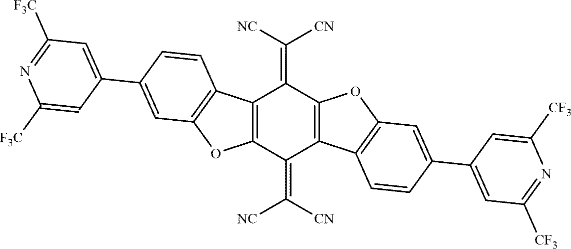 [SMILES: N#CC(C#N)=c1c2oc3cc(-c4cc(C(F)(F)F)nc(C(F)(F)F)c4)ccc3c2c(=C(C#N)C#N)c2oc3cc(-c4cc(C(F)(F)F)nc(C(F)(F)F)c4)ccc3c12] 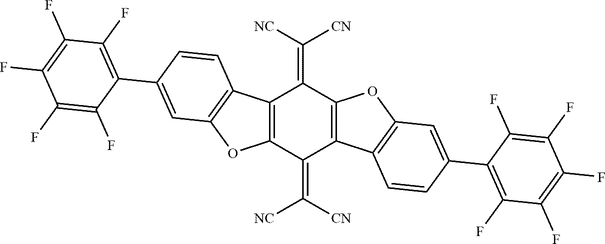 [SMILES: N#CC(C#N)=c1c2oc3cc(-c4c(F)c(F)c(F)c(F)c4F)ccc3c2c(=C(C#N)C#N)c2oc3cc(-c4c(F)c(F)c(F)c(F)c4F)ccc3c12] 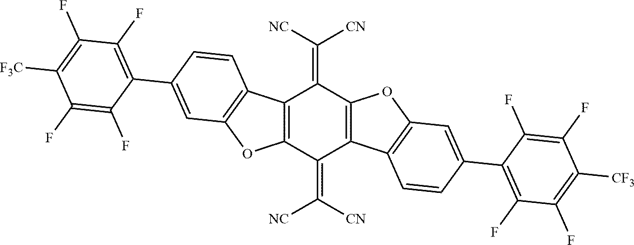 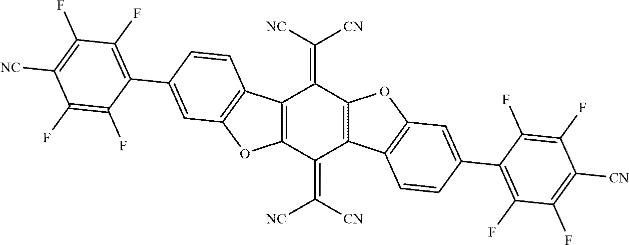 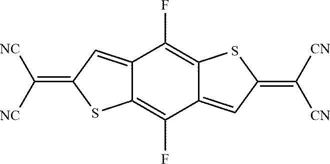 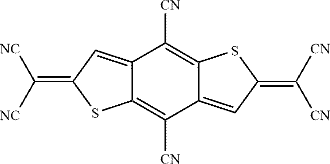 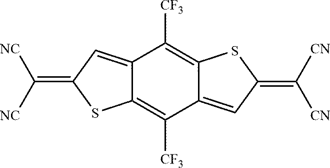 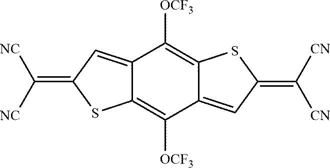 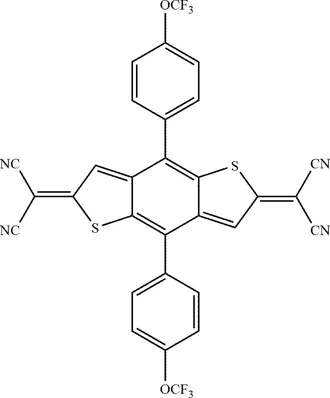 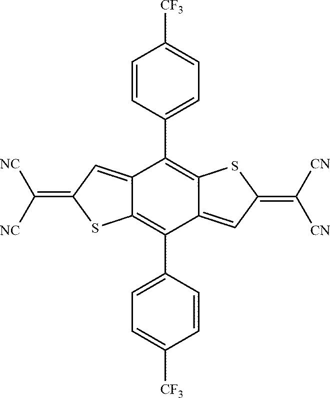 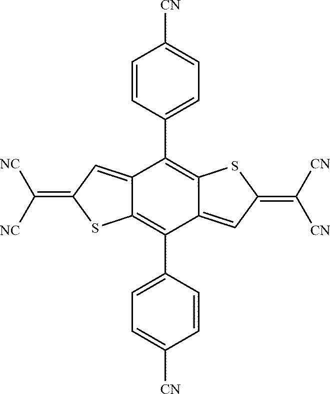 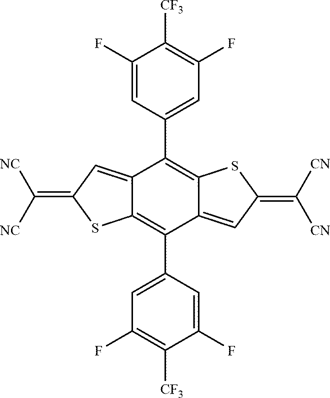 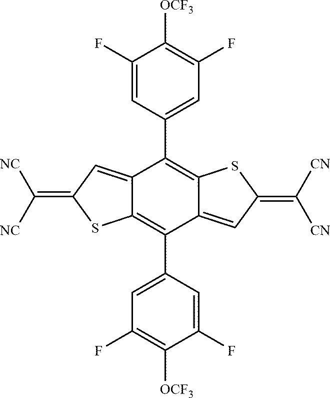 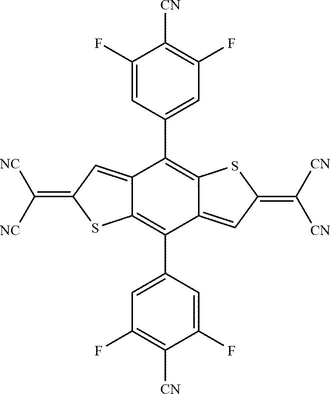 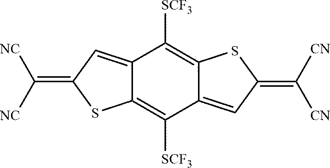 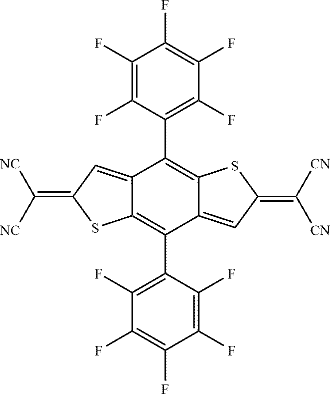 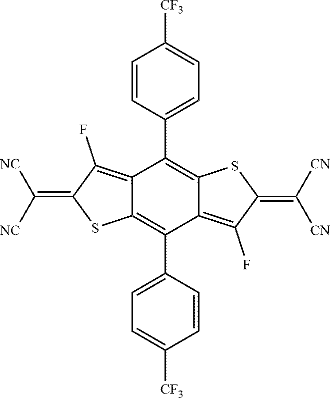 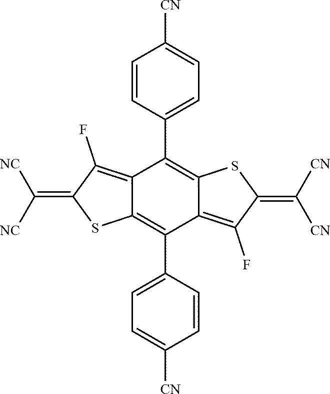 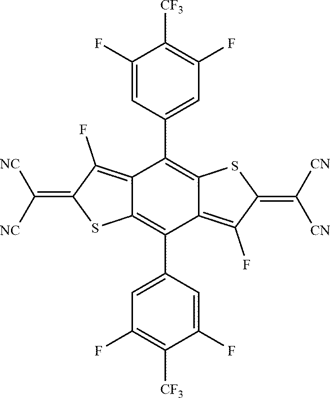 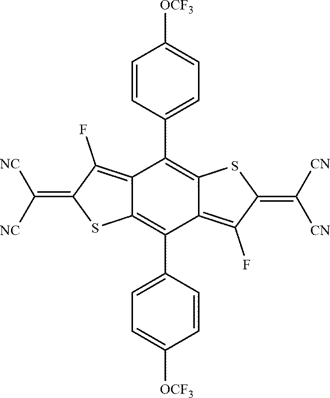 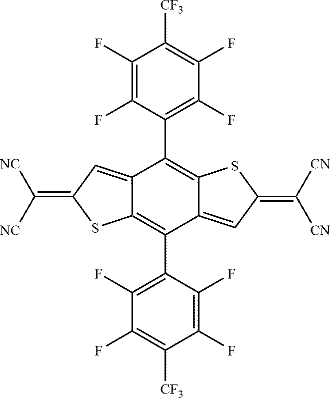 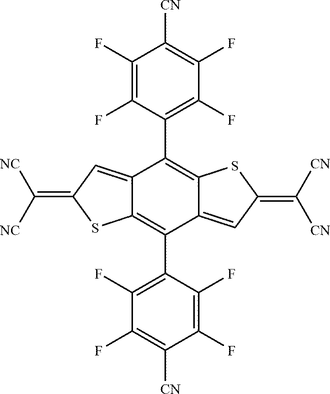 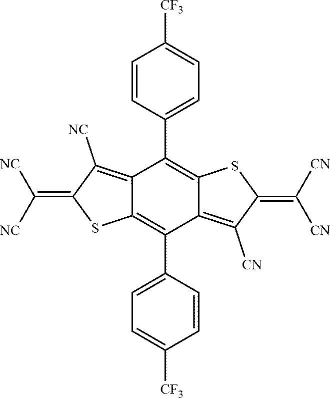 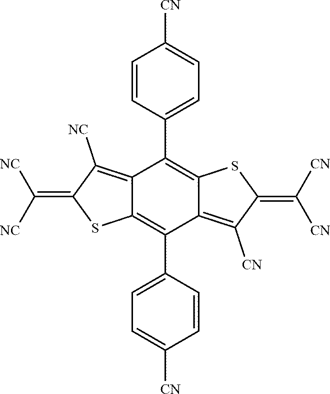 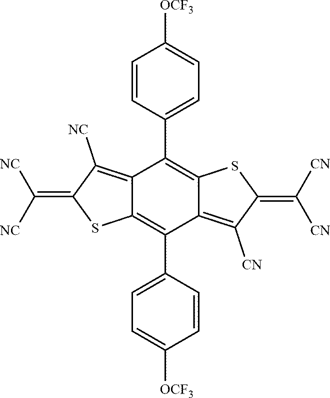 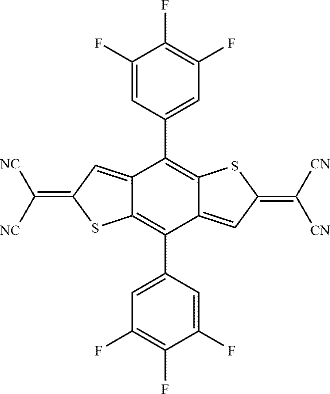 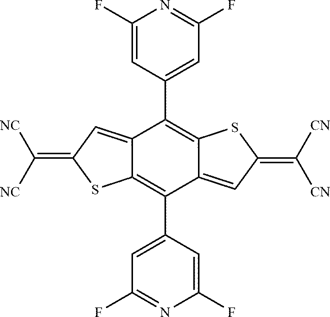 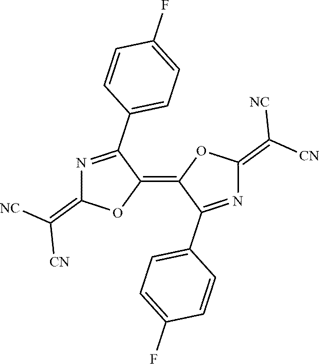 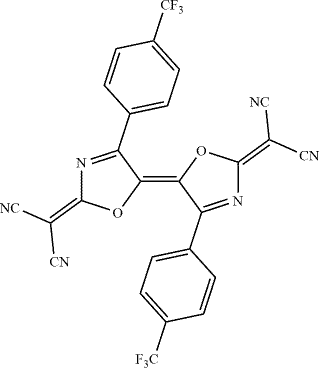 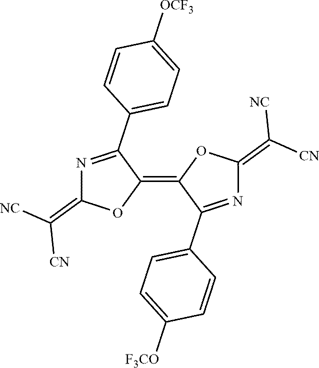 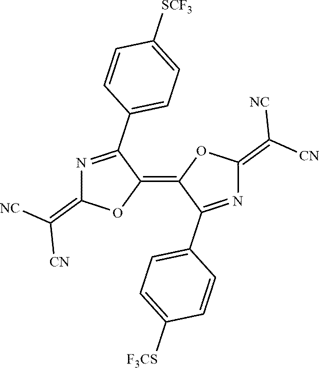 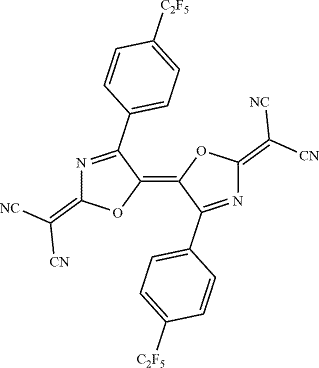 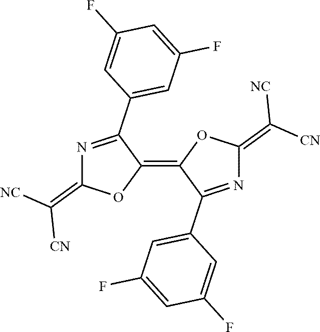 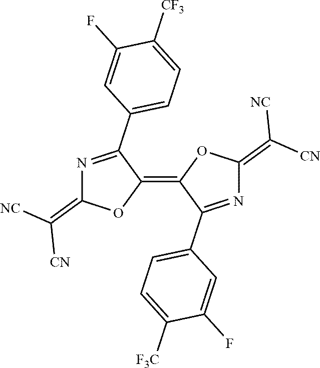 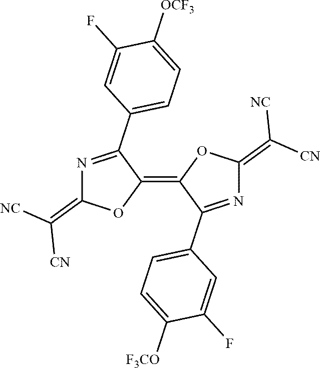 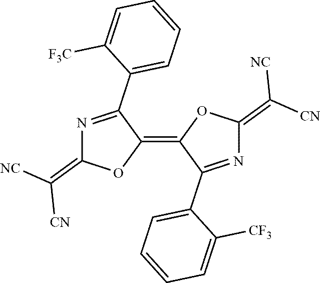 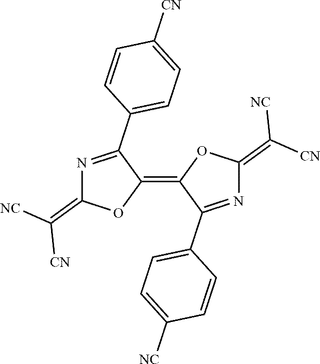 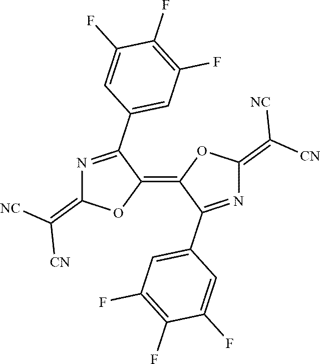 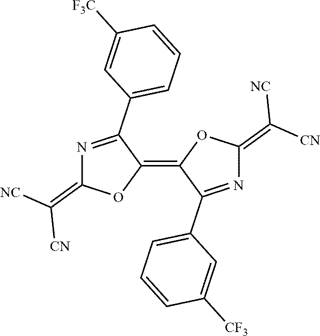 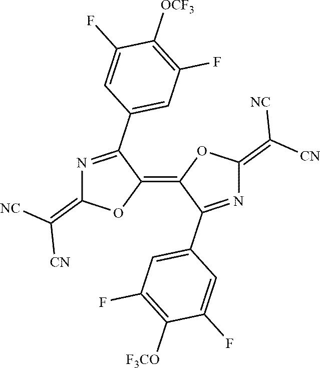 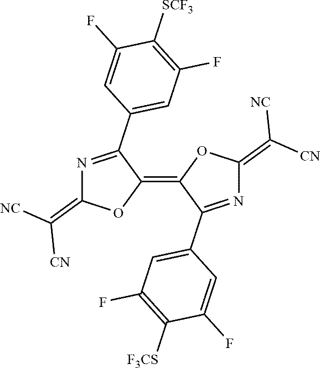 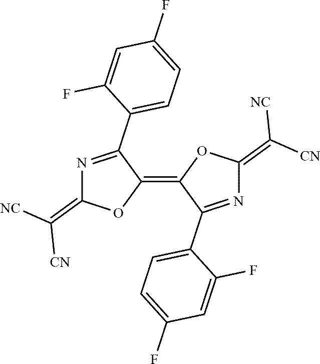 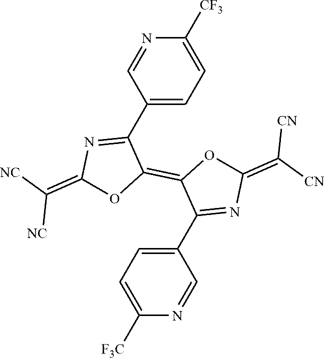 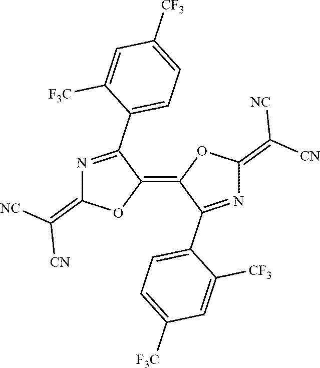 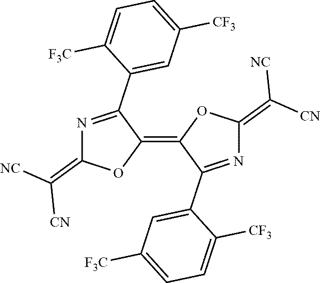 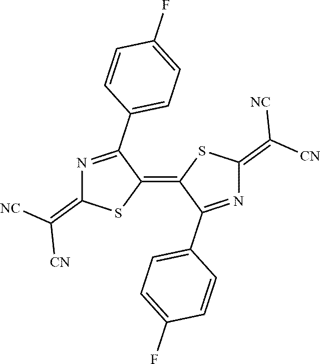 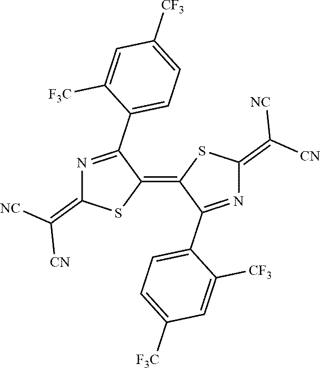 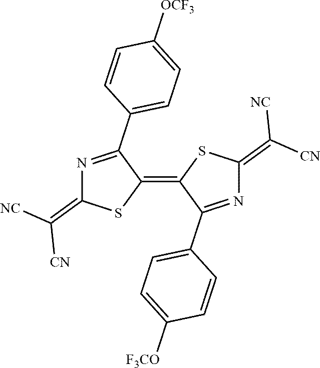 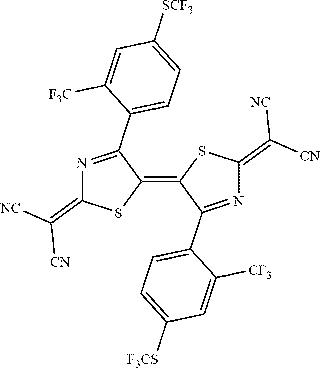
.

7. The organic electroluminescent device according to claim 1, wherein the metal material of the metal layer is selected from the group consisting of: Yb, Li, Rb, Cs, Be, Mg, Ca, Sr, Ba, La, Ce, Pr, Nd, Sm, Eu, Y, Mn, Ag and combinations of the above multiple metals; preferably, the metal material of the metal layer is Yb.

8. The organic electroluminescent device according to claim 1, wherein the work function of the metal material of the metal layer is less than 4.0 eV.

9. The organic electroluminescent device according to claim 1, wherein the metal layer is formed by one elemental metal, or is formed by two or more elemental metals.

10. The organic electroluminescent device according to claim 1, wherein the metal layer has a thickness ranging from 0.1 nm to 20 nm, preferably from 0.1 nm to 5 nm.

11. The organic electroluminescent device according to claim 1, wherein LUMO_{first organic material} - work functionₘₑₜₐₗ < 2.05 eV.

12. The organic electroluminescent device according to claim 1, wherein the first organic layer has a thickness ranging from 0.1 nm to 30 nm, preferably from 0.1 nm to 15 nm.

13. The organic electroluminescent device according to claim 1, wherein in the second organic layer, the first organic material accounts for 4% to 49%, preferably 5% to 35%, more preferably 5% to 30%, of the total mass of the second organic layer.

14. The organic electroluminescent device according to claim 1, wherein at least one of the first organic layer and the metal layer forms a discontinuous thin film.

15. The organic electroluminescent device according to claim 1, wherein the first organic layer is in direct contact with the second organic layer.

16. The organic electroluminescent device according to claim 1, wherein HOMO_{second organic material} - LUMO_{first organic material} ≤ 0.8 eV; preferably, HOMO_{second organic material} - LUMO_{first organic material} ≤ 0.6 eV.

17. The organic electroluminescent device according to claim 1, wherein the HOMO energy level of the second organic material is ≥ 5.1 eV.

18. The organic electroluminescent device according to claim 1, wherein the visible light transmittance of the connection layer is greater than 70%; preferably, the visible light transmittance of the connection layer is greater than 80%.

19. The organic electroluminescent device according to claim 1, wherein the at least two light-emitting units are capable of emitting light of a same color or light of different colors.

20. An electronic assembly, comprising the organic electroluminescent device according to claim 1.
